(19) United States
(12) Patent Application Publication
(10) Pub. No.: US 2025/0357290 A1
(43) Pub. Date: Nov. 20, 2025

(54) SEMICONDUCTOR PACKAGE

(71) Applicant: SAMSUNG ELECTRONICS CO., LTD., Suwon-si (KR)

(72) Inventors: Junho LEE, Suwon-si (KR); Minwoo CHO, Suwon-si (KR)

(73) Assignee: SAMSUNG ELECTRONICS CO., LTD., Suwon-si (KR)

(21) Appl. No.: 18/978,932

(22) Filed: Dec. 12, 2024

(30) Foreign Application Priority Data
May 14, 2024 (KR) 10-2024-0063414

(51) Int. Cl. H01L 23/498; H01L 23/367; H01L 25/065

(52) U.S. Cl. CPC H01L 23/49816; H01L 23/3675; H01L 23/49838; H01L 25/0655

(57) ABSTRACT

A semiconductor package may include a package substrate including: a substrate body including a top surface and a bottom surface opposite to the top surface; and a plurality of substrate pads spaced apart from each other on the bottom surface. The semiconductor package may further include a plurality of connection balls connected to the plurality of substrate pads, wherein the plurality of connection balls include: a metal core solder ball including a metal core; and a plurality of core-free solder balls that each have a same volume as a volume of the metal core solder ball.

### CROSS-REFERENCE TO RELATED APPLICATION

This application is based on and claims priority under 35 U.S.C. § 119 to Korean Patent Application No. 10-2024-0063414, filed on May 14, 2024, in the Korean Intellectual Property Office, the disclosure of which is incorporated by reference herein in its entirety.

### BACKGROUND

### 1. Field

Embodiments of the present disclosure relate to a semiconductor package.

### 2. Brief Description of Related Art

Due to the miniaturization of electronic devices, the size of semiconductor packages is becoming increasingly smaller, thinner, and lighter. In addition, as the functions of electronic devices become more complicated, a module semiconductor package having a plurality of semiconductor packages mounted on a package substrate has become widely used. As a result, warpage occurs in which the package substrate is bent due to thermal and mechanical stress applied to the package substrate included in the semiconductor package or the module semiconductor package.

### SUMMARY

According to embodiments of the present disclosure, a board level semiconductor package is provided that is capable of easily electrically connecting a semiconductor package or a module semiconductor package including a package substrate to a board substrate in which warpage is generated.

According to embodiments of the present disclosure, a semiconductor package may be provided and include: a package substrate including: a substrate body including a top surface and a bottom surface opposite to the top surface; and a plurality of substrate pads spaced apart from each other on the bottom surface. The semiconductor package may further include a plurality of connection balls connected to the plurality of substrate pads, wherein the plurality of connection balls include: a metal core solder ball including a metal core; and a plurality of core-free solder balls that each have a same volume as a volume of the metal core solder ball.

According to embodiments of the present disclosure, a semiconductor package may be provided and include a package substrate including: a substrate body including a top surface and a bottom surface opposite to the top surface; and a plurality of substrate pads spaced apart from each other on the bottom surface. The semiconductor package may further include a plurality of connection balls connected to the plurality of substrate pads, wherein the plurality of connection balls include: a first metal core solder ball including a first metal core; a plurality of core-free solder balls; and a second metal core solder ball between the first metal core solder ball and the plurality of core-free solder balls and including a second metal core having a diameter greater than a diameter of the first metal core, wherein the first metal core solder ball, the second metal core solder ball, and the plurality of core-free solder balls have a same volume as each other.

According to embodiments of the present disclosure, a semiconductor package may be provided and include a package substrate including: a substrate body including a top surface and a bottom surface opposite to the top surface, and a plurality of substrate pads spaced apart from each other on the bottom surface. The semiconductor package may further include a plurality of connection balls connected to the plurality of substrate pads, wherein the package substrate has negative warpage such that the package substrate is convex downward, wherein the plurality of connection balls may include: a first metal core solder ball at a center of the package substrate and including a first metal core; a second metal core solder ball adjacent to the first metal core solder ball and including a second metal core having a diameter greater than a diameter of the first metal core; and a plurality of core-free solder balls adjacent to the second metal core solder ball, and wherein the first metal core solder ball, the second metal core solder ball, and the plurality of core-free solder balls have a same volume as each other.

### BRIEF DESCRIPTION OF DRAWINGS

Embodiments will be more clearly understood from the following detailed description taken in conjunction with the accompanying drawings in which:

FIG. 1 is a cross-sectional view illustrating a semiconductor package according to an embodiment;

FIG. 2 is a cross-sectional view illustrating coupling between a board substrate and a modular semiconductor package of FIG. 1;

FIG. 3 is a partially enlarged cross-sectional view of the semiconductor package shown in FIG. 1;

FIG. 4 is an enlarged cross-sectional view of a metal core solder ball that may be used in the semiconductor package shown in FIG. 1;

FIG. 5 is a planar layout diagram illustrating connection balls arranged on substrate pads of a package substrate of FIGS. 1 and 3;

FIGS. 6A to 6J are perspective views illustrating a process of forming solder balls on substrate pads of the package substrate of FIG. 5;

FIG. 7 is a planar layout diagram illustrating connection balls arranged on substrate pads of a package substrate according to an embodiment;

FIG. 8 is a cross-sectional view illustrating a semiconductor package according to an embodiment;

FIG. 9 is a partially enlarged cross-sectional view of the semiconductor package shown in FIG. 8;

FIG. 10 is a partially enlarged planar layout diagram of the semiconductor package shown in FIG. 8;

FIG. 11 is a cross-sectional view illustrating a semiconductor package according to an embodiment;

FIG. 12 is a cross-sectional view illustrating a semiconductor package including a package substrate having negative warpage according to an embodiment;

FIG. 13 is a planar layout diagram illustrating connection balls arranged on substrate pads of the package substrate of FIG. 12;

FIG. 14 is a planar layout diagram illustrating connection balls arranged on substrate pads of a package substrate according to an embodiment;

FIG. 15 is a cross-sectional view illustrating a semiconductor package including a package substrate having negative warpage as a semiconductor package according to an embodiment;

FIG. 16 is a partially enlarged cross-sectional view of the semiconductor package shown in FIG. 15;

FIG. 17 is a partially enlarged planar layout diagram of the semiconductor package shown in FIG. 15;

FIG. 18 is a cross-sectional view illustrating a semiconductor package including a package substrate having negative warpage according to an embodiment;

FIG. 19 is a cross-sectional view illustrating a semiconductor package according to an embodiment; and

FIG. 20 is a block diagram schematically illustrating a configuration of a semiconductor package according to an embodiment.

### DETAILED DESCRIPTION

Hereinafter, non-limiting example embodiments of the present disclosure will be described in detail with reference to the accompanying drawings. However, the present disclosure is not limited to the example embodiments described below, and embodiments of the present disclosure may have various other forms. The following example embodiments are provided to sufficiently convey the scope of the present disclosure to those skilled in the art.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

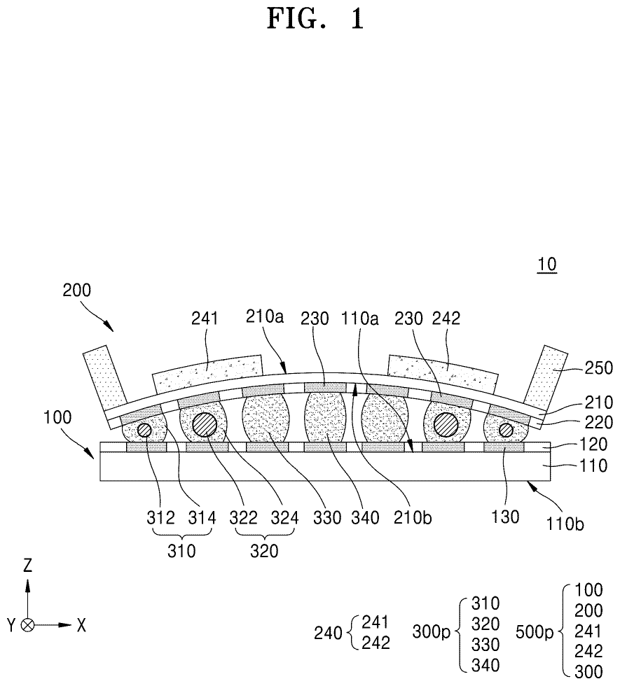

FIG. 1 is a cross-sectional view illustrating a semiconductor package 10 according to an embodiment.

Referring to FIG. 1, a semiconductor package 10 may include a board substrate 100, a package substrate 200, a modular semiconductor package 500 including a plurality of semiconductor devices (e.g., a first semiconductor device 241 and a second semiconductor device 242), and connection balls 300. In the drawings, a first horizontal direction (X direction) may be a direction horizontal to the board substrate 100, and a second horizontal direction (Y direction) may be a direction horizontal to the board substrate 100 and perpendicular to the first horizontal direction (X direction). A vertical direction (Z direction) may be a direction orthogonal to the board substrate 100. The semiconductor package 10 may be a board level semiconductor package.

The board substrate 100 may include a board body 110 having a top surface 110a and a bottom surface 110b, a plurality of board pads 130 arranged to be spaced apart from each other on the top surface 110a of the board body 110, and a board protection layer 120 insulating the board pads 130.

The board body 110 may include at least one from among a prepreg resin, a thermosetting epoxy resin, a thermoplastic epoxy resin, and a resin including a filler. The board substrate 100 may refer to the board body 110 in a narrow sense (a limited sense). The board substrate 100 may be a mother board substrate. The board substrate 100 may be a printed circuit board (PCB).

The board pads 130 may be arranged to be spaced apart from each other in the first horizontal direction (X direction) and the second horizontal direction (Y direction) on the top surface 110a of the board body 110. The board pads 130 may be a single layer or a composite layer of a metal such as tin, silver, or copper. The board protection layer 120 may be arranged on the top surface 110a of the board body 110 in regions other than the board pads 130. The board protection layer 120 may be a solder resist layer.

The package substrate 200 may include a substrate body 210 having a top surface 210a and a bottom surface 210b, a plurality of substrate pads 230 arranged to be spaced apart from each other on the bottom surface 210b of the substrate body 210, and a substrate protection layer 220 insulating the substrate pads 230.

The substrate body 210 may include at least one from among a prepreg resin, a thermosetting epoxy resin, a thermoplastic epoxy resin, and a resin including a filler. The package substrate 200 may be the substrate body 210 in a narrow sense (a limited sense). The package substrate 200 may be a printed circuit board (PCB).

The package substrate 200 may have a warpage in a manufacturing process. In some embodiments, the package substrate 200 (e.g., the substrate body 210) may have a positive warpage convex upward. The substrate pads 230 may be arranged on the bottom surface 210b of the substrate body 210 to be spaced apart from each other in the first horizontal direction (X direction) and the second horizontal direction (Y direction).

The substrate pads 230 may be a single layer or a composite layer of a metal such as tin, silver, or copper. The substrate protection layer 220 may be arranged on the bottom surface 210b of the substrate body 210 in regions other than the substrate pads 230. The substrate protection layer 220 may be a solder resist layer.

A plurality of semiconductor devices (e.g., a first semiconductor device 241 and a second semiconductor device 242) are spaced apart from each other on the package substrate 200, that is, the top surface 210a of the substrate body 210. The semiconductor devices (e.g., the first semiconductor device 241 and the second semiconductor device 242) may include a memory semiconductor package and a non-memory semiconductor package. The semiconductor devices may include a first semiconductor device 241 and a second semiconductor device 242. In a cross-sectional view of the present embodiment, the semiconductor devices (e.g., the first semiconductor device 241 and the second semiconductor device 242) include two semiconductor devices, but only at least one semiconductor device may be arranged. The plurality of semiconductor devices (e.g., the first semiconductor device 241 and the second semiconductor device 242) may be mounted on the substrate body 210 through a flip chip method, a wire bonding method, or the like. The method in which the plurality of semiconductor devices (e.g., the first semiconductor device 241 and the second semiconductor device 242) are mounted on the substrate body 210 is not limited thereto.

A structure including the board substrate 100, the package substrate 200, and connection balls 300 may be referred to as a modular semiconductor package 500, and thus, the semiconductor devices (e.g., the first semiconductor device 241 and the second semiconductor device 242) arranged on the substrate body 210 may be combined with the board substrate 100 by using the connection balls 300. In this embodiment, the plurality of semiconductor devices (e.g., the first semiconductor device 241 and the second semiconductor device 242) are arranged on the package substrate 200, but depending on embodiments, semiconductor chips may be arranged on the package substrate 200.

In addition, the package substrate 200 may further include stiffeners 250 extending along the outer edges of the substrate body 210 on the top surface 210a of the substrate body 210 and blocking the plurality of semiconductor devices (e.g., the first semiconductor device 241 and the second semiconductor device 242) in the lateral direction (X direction and/or Y direction). Each of the stiffeners 250 may have a frame shape, and the stiffeners 250 may serve to reduce the warpage of the substrate body 210 in a package forming process. In an embodiment, the stiffeners 250 may include a metallic material such as copper (Cu). However, the material included in the stiffeners 250 is not limited to a metallic material, and may include glass fibers.

Connection balls 300 may be arranged between the board substrate 100 and the package substrate 200 to electrically connect the board pads 130 and the substrate pads 230 to each other. The connection balls 300 may include a plurality of first metal core solder balls 310, second metal core solder balls 320, first core-free solder balls 330, and second core-free solder balls 340.

The first metal core solder ball 310 may include a first metal core 312 and a first core solder layer 314 surrounding the first metal core 312. The second metal core solder ball 320 may include a second metal core 322 and a second core solder layer 324 surrounding the second metal core 322. In this case, a volume of the first metal core solder ball 310 is the same as a volume of the second metal core solder ball 320, and a diameter of the second metal core 322 may be greater than a diameter of the first metal core 312. In an embodiment, the first metal core 312 and the second metal core 322 may have a spherical shape. However, the shapes of the first metal core 312 and the second metal core 322 are not necessarily limited to a spherical shape, and when they have other shapes, a height of the second metal core 322 in the vertical direction (Z direction) may be greater than a height of the first metal core 312 in the vertical direction (Z direction). The first metal core 312 and the second metal core 322 may include at least one from among copper (Cu), nickel (Ni), and a polymer (e.g., a polymer coated with copper or a polymer coated with nickel), and the first metal core 312 and the second metal core 322 may have melting points of 260° C. or more. The first core solder layer 314 and the second core solder layer 324 may include a solder composition including Sn as a base metal and Ag, Cu, Bi, and Ni as auxiliary metals.

The plurality of core-free solder balls may include the first core-free solder ball 330 and the second core-free solder ball 340. The core-free solder balls may mean solder balls having no metal core. The second core-free solder ball 340 may be a core-free solder ball located in the center of the package substrate 200, and the first core-free solder balls 330 may be core-free solder balls spaced apart from each other in the first horizontal direction (X direction) with the second core-free solder ball 340 therebetween.

A height of the second core-free solder ball 340 in the vertical direction (Z direction) may be greater than a height of each of the first core-free solder balls 330 in the vertical direction (Z direction). The package substrate 200 shown in FIG. 1 may have a positive warpage having a central portion convex upward. Therefore, it is beneficial to overcome problems caused by vertical gaps due to the warpage when the connection balls 300 attached to the package substrate 200 are attached to the board pads 130. The vertical gap between the package substrate 200 and the board substrate 100 at the central portion of the package substrate 200 may be relatively great compared to the vertical gap between the package substrate 200 and the board substrate 100 at the outer peripheral portions of the package substrate 200. Therefore, in order to stably connect the substrate pad 230 located in the central portion of the package substrate 200 with the board pad 130 located in the central portion of the board substrate 100, the second core-free solder ball 340 has a relatively great height in the vertical direction (Z direction). The height of the second core-free solder ball 340 in the vertical direction (Z direction) is increased so that the connection (e.g., solderability) of the solder ball may be improved.

The first core-free solder ball 330 and the second core-free solder ball 340 may include a solder material. In this case, the first core solder layer 314 and the second core solder layer 324 may include a same solder material. The plurality of core-free solder balls (e.g., the first core-free solder balls 330 and the second core-free solder balls 340), the first metal core solder balls 310, and the second metal core solder balls 320 may be arranged on the substrate pads 230 to electrically connect the board pads 130 to the substrate pads 230. Strengths of the first metal core solder balls 310 and the second metal core solder balls 320 may be greater than strengths of the core-free solder balls (e.g., the first core-free solder balls 330 and the second core-free solder balls 340).

As described above, the package substrate 200 may have a warpage in a manufacturing process. For example, as described above, the package substrate 200, that is, the substrate body 210, may have an upwardly convex positive warpage. Accordingly, the first metal core solder balls 310 and the second metal core solder balls 320 may be arranged on the outer peripheral portions of the package substrate 200. In particular, the first metal core solder balls 310 may be arranged at the outermost peripheral portion of the package substrate 200, and the second metal core solder balls 320 may be arranged closer to the central portion of the package substrate 200 than the first metal core solder balls 310. Since the metal core solder balls are arranged on the outer peripheral portions of the package substrate 200 having a positive warpage, short-circuit occurrence of the connection balls may be prevented in the outer peripheral portions of the package substrate 200. When the volume of the solder material of the connection balls arranged on the outer peripheral portions of the package substrate 200 is too great, the probability of occurrence of a short circuit with other adjacent connection balls is high. To prevent this, in order to reduce the volume of the solder material contained in the connection balls in the outer peripheral portions, the connection balls (e.g., the first metal core solder ball 310 and the second metal core solder ball 320) arranged on the outer peripheral portions may include a metal core.

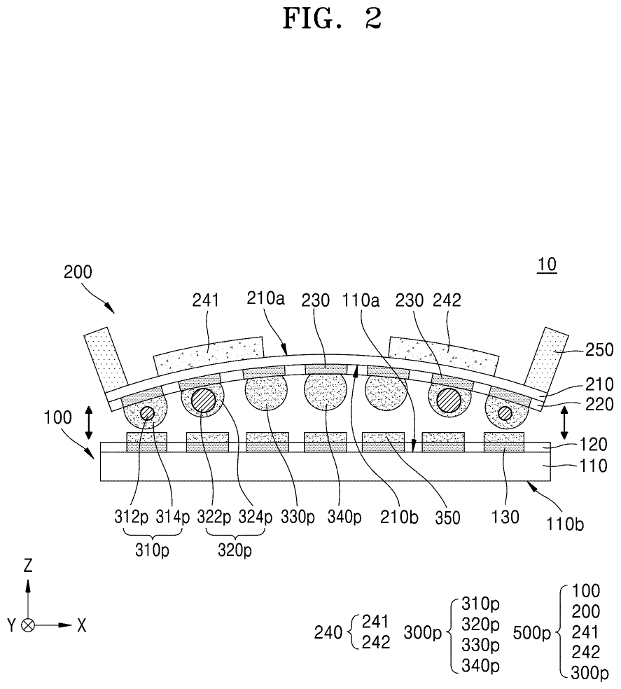

FIG. 2 is a cross-sectional view illustrating a coupling between a board substrate and a modular semiconductor package 500 of FIG. 1.

Specifically, in FIG. 2, the same reference numerals as in FIG. 1 denote the same members. Description of FIG. 2 may be briefly provided or omitted when redundant with respect to descriptions provided with reference to FIG. 1. The semiconductor package 10 may be a modular semiconductor package 500p including a board substrate 100, a package substrate 200, and connection balls 300p and thus, the board substrate 100 may be combined with semiconductor devices (e.g., the first semiconductor device 241 and the second semiconductor device 242) mounted on the package substrate 200 using the connection balls 300p.

The semiconductor package 10 may include a modular semiconductor package 500p having connection balls 300p formed at a lower portion of and on the board substrate 100, and the board pads 130 of the board substrate 100 and the connection balls 300p may be coupled with and closely contacting each other using a solder paste 350. Unlike the connection balls 300 shown in FIG. 1, the connection balls 300p shown in FIG. 2 are connection balls that are not fused with the solder paste 350.

More specifically, the board substrate 100 may include a board body 110 having a top surface 110a and a bottom surface 110b, a plurality of board pads 130 arranged to be spaced apart from each other on the top surface 110a of the board body 110, and a board protection layer 120 insulating the board pads 130.

The package substrate 200 may include a substrate body 210 having a top surface 210a and a bottom surface 210b, a plurality of substrate pads 230 arranged to be spaced apart from each other on the bottom surface 210b of the substrate body 210, and a substrate protection layer 220 insulating the substrate pads 230. The connection balls 300p are arranged on the substrate pads 230 arranged on the bottom surface 210b of the substrate body 210.

The connection balls 300p may include a plurality of metal core solder balls (e.g., first metal core solder balls 310p the second metal core solder balls 320p) and a plurality of core-free solder balls (e.g., first core-free solder balls 330p and second core-free solder balls 340p). Unlike the plurality of metal core solder balls (e.g., the first metal core solder balls 310 and the second metal core solder balls 320) and the plurality of core-free solder balls (e.g., the first core-free solder balls 330 and the second core-free solder balls 340) shown in FIG. 1, the plurality of core-free solder balls (e.g., the first metal core solder balls 310p and the second metal core solder balls 320p) and the plurality of core-free solder balls (e.g., the first core-free solder balls 330p and the second core-free solder balls 340p) shown in FIG. 2 are connection balls before being fused with the solder paste 350. Therefore, the widths of the metal core solder balls (e.g., the first metal core solder balls 310p and the second metal core solder balls 320p) and the core-free solder balls (e.g., the first core-free solder balls 330p and the second core-free solder balls 340p) in the lateral direction (X direction and/or Y direction) are the same as the heights of the metal core solder balls (e.g., the first metal core solder balls 310p and the second metal core solder balls 320p) and the core-free solder balls (e.g., the first core-free solder balls 330p and the second core-free solder balls 340p) in the vertical direction (Z direction). A plurality of solder pastes 350 may have the same volume as each other. Therefore, even if the connection balls 300p of FIG. 2 are fused with the solder pastes 350, the connection balls 300 may maintain the same volume as shown in FIG. 1.

The semiconductor devices (e.g., the first semiconductor device 241 and the second semiconductor device 242) arranged to be spaced apart from each other are arranged on the top surface 210a of the substrate body 210. The connection balls 300p may include a plurality of metal core solder balls (e.g., the first metal core solder balls 310p and the second metal core solder balls 320p) and a plurality of core-free solder balls (e.g., the first core-free solder balls 330p and the second core-free solder balls 340p). The package substrate 200, that is, the substrate body 210, may have a positive warpage convex upward.

Since the package substrate 200 has a positive warpage that is convex upward, the gap between the outer peripheral portion of the package substrate 200 and the outer peripheral portion of the board substrate 100 may be small, and the gap between the central portion of the package substrate 200 and the central portion of the board substrate 100 may be large. Accordingly, even if the gap between the package substrate 200 and the board substrate 100 is narrowed, metal core solder balls (e.g., the first metal core solder balls 310p and the second metal core solder balls 320p) may be arranged on the outer peripheral portions of the package substrate 200, to thereby suppress the occurrence of short circuits between neighboring solder balls and to improve package flatness.

The first core-free solder balls 330p and the second core-free solder balls 340p may be arranged at a central portion of the package substrate 200. The first core-free solder balls 330p and the second core-free solder balls 340p may include core-free solder layers having volumes greater than volumes of the first core solder layer 314p of the first metal core solder balls 310p and the second core solder layer 324p of the second metal core solder balls 320p. As the volumes of the first core solder layer 314p and the second core solder layer 324p increase, a solderability such as wetting of the connection balls may increase. Accordingly, even if the gap between the package substrate 200 and the board substrate 100 is large, the package substrate 200 and the board substrate 100 may be easily connected in the central portion of the package substrate 200 by using the core-free solder balls (e.g., the first core-free solder balls 330p and the second core-free solder balls 340p).

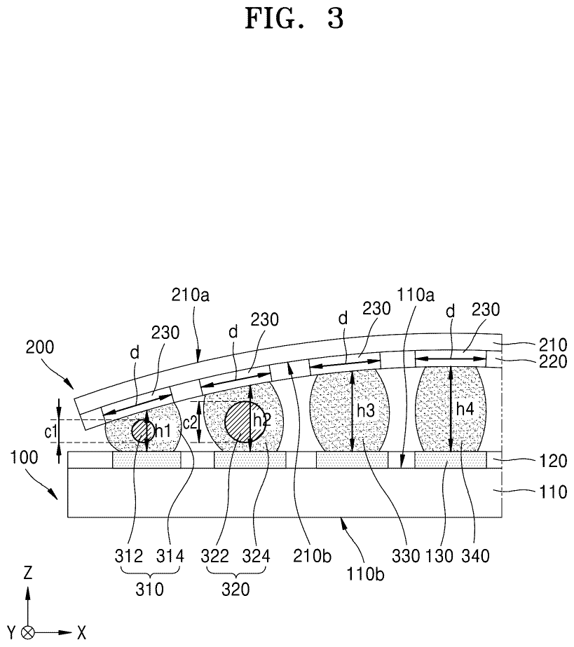

FIG. 3 is a partially enlarged cross-sectional view of the semiconductor package 10 shown in FIG. 1.

Repeated descriptions of components already mentioned with reference to FIG. 1 may be omitted or simplified below.

Referring to FIG. 3, a plurality of substrate pads 230 may have the same diameter d. In addition, since the package substrate 200 has a positive warpage, heights of the connection balls 300 increase in the vertical direction (Z direction) from the outer peripheral portion of the package substrate 200 to the central portion thereof. That is, a height h1 of a first metal core solder ball 310 in the vertical direction (Z direction) is less than a height h2 of a second metal core solder ball 320 in the vertical direction (Z direction), and the height h2 of the second metal core solder ball 320 in the vertical direction (Z direction) is less than a height h3 of a first core-free solder ball 330 in the vertical direction (Z direction). In addition, the height h3 of the first core-free solder ball 330 in the vertical direction (Z direction) is less than a height h4 of a second core-free solder ball 340 in the vertical direction (Z direction).

However, since the volume of each of the connection balls 300 is the same, the width of the first metal core solder ball 310 in the lateral direction (X direction and/or Y direction) is greater than the width of the second metal core solder ball 320 in the lateral direction (X direction and/or Y direction), and the width of the second metal core solder ball 320 in the lateral direction (X direction and/or Y direction) is greater than the width of the first core-free solder ball 330 in the lateral direction (X direction and/or Y direction). In addition, the width of the first core-free solder ball 330 in the lateral direction (X direction and/or Y direction) is greater than the width of the second core-free solder ball 340 in the lateral direction (X direction and/or Y direction).

In addition, a diameter c1 of the first metal core 312 may be less than a diameter c2 of the second metal core 322. Since the gap between the package substrate 200 and the board substrate 100 is the narrowest at the outermost peripheral portion of the package substrate 200, the diameter c1 of the first metal core 312 may be less than the diameter of the second metal core c2.

According to an embodiment, the diameter c1 of the first metal core 312 may be 0.3 to 0.9 times a height h1 of the adjacent core-free solder ball in the vertical direction (Z direction), and the diameter c2 of the second metal core 322 may be 0.5 to 0.9 times a height h2 of the adjacent core-free solder ball in the vertical direction (Z direction). For example, the diameter c1 of the first metal core 312 may be 0.3 to 0.9 times a height h3 of the first core-free solder ball 330 in the vertical direction (Z direction). In addition, the diameter c2 of the second metal core 322 may be 0.5 to 0.9 times the height h3 of the first core-free solder ball 330 in the vertical direction (Z direction). When the diameter c1 of the first metal core 312 or the diameter c2 of the second metal core 322 is greater than 0.9 times the height of the closest core-free solder ball in the vertical direction (Z direction), the amount of the first core solder layer 314 and the second core solder layer 324 may be too small, and thus the solderability between the substrate pad 230 and the board pad 130 may be degraded. When the diameter c1 of the first metal core 312 is less than 0.3 times the height of the closest core-free solder ball in the vertical direction (Z direction), or when the diameter c2 of the second metal core 322 is less than 0.5 times the height of the core-free solder ball in the vertical direction (Z direction), the probability of a short circuit occurring in a relationship with an adjacent connection ball due to too a small amount of volume of the metal core may be increased, and the stress burden applied to the first metal core solder ball 310 and the second metal core solder ball 320 may be increased.

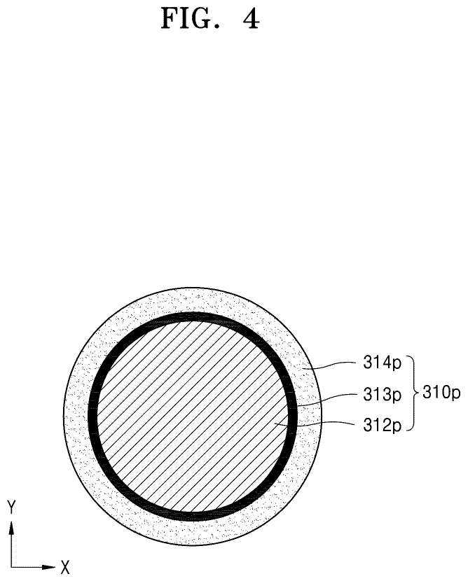

FIG. 4 is an enlarged cross-sectional view of the first metal core solder ball 310p that may be used in the semiconductor package 10 shown in FIG. 2. Hereinafter, the first metal core solder ball 310p will be described with reference to FIG. 4 along with FIG. 2.

Specifically, as described above, the first metal core solder ball 310p including the first metal core 312p and the first core solder layer 314p surrounding the first metal core 312p, and the second metal core solder ball 320p including the second metal core 322p and the second core solder layer 324p surrounding the second metal core 322p may be used in the semiconductor package 10 of FIG. 2.

As illustrated in FIG. 4, a metal core solder ball (e.g., the first metal core solder ball 310p) including a metal core (e.g., the first metal core 312p), an interface layer 313p surrounding the metal core (e.g., the first metal core 312p), and a core solder layer (e.g., the first core solder layer 314p) surrounding the interface layer 313p may be used in the semiconductor package 10 of FIG. 2. The interface layer 313p may be a material layer to facilitate bonding between the metal core (e.g., the first metal core 312p) and the core solder layer (e.g., the first core solder layer 314p). In some embodiments, the interface layer 313p may be a nickel (Ni) layer. The first metal core solder ball 310p illustrated in FIG. 4 is a detailed view of the first metal core solder ball 310p illustrated in FIG. 2. Although only the first metal core solder ball 310p is illustrated in FIG. 4, the second metal core solder ball 320p may also have a structure similar to a structure of the first metal core solder ball 310p, except that the volumes of the metal core and the core solder layer are different from the volumes of the second metal core solder ball 320p.

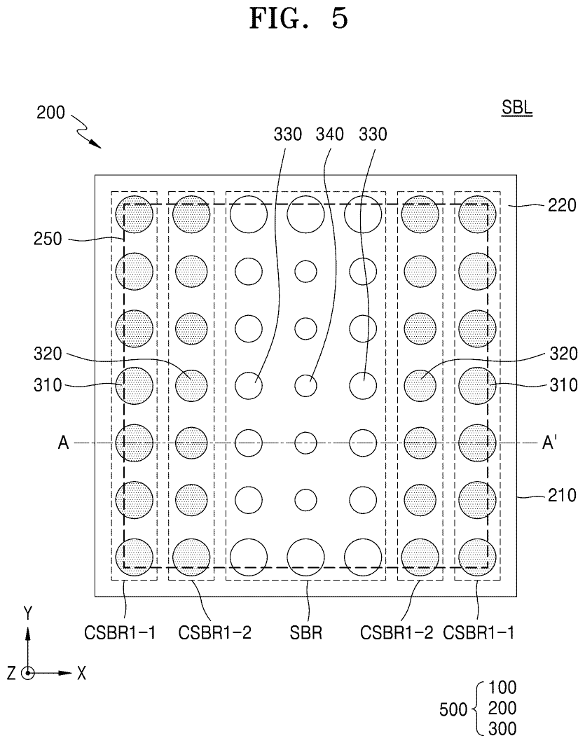

FIG. 5 is an example of a planar layout diagram showing connection balls 300 arranged on the substrate pads 230 of the package substrate 200 of FIGS. 1 and 3.

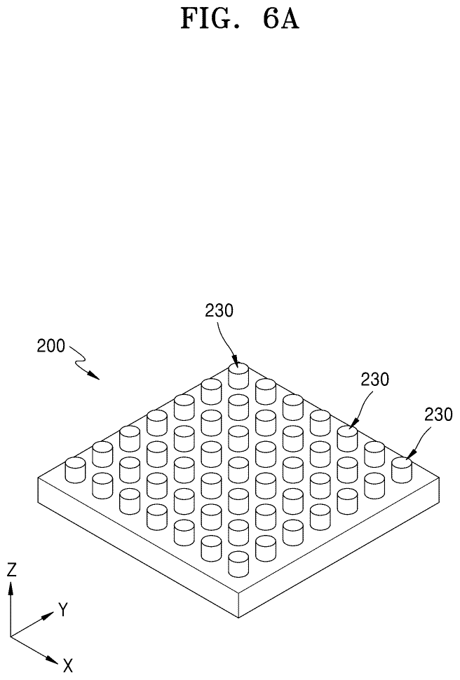

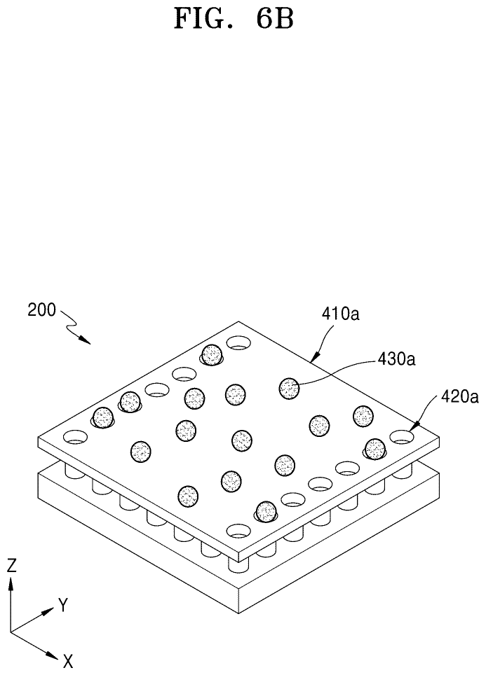

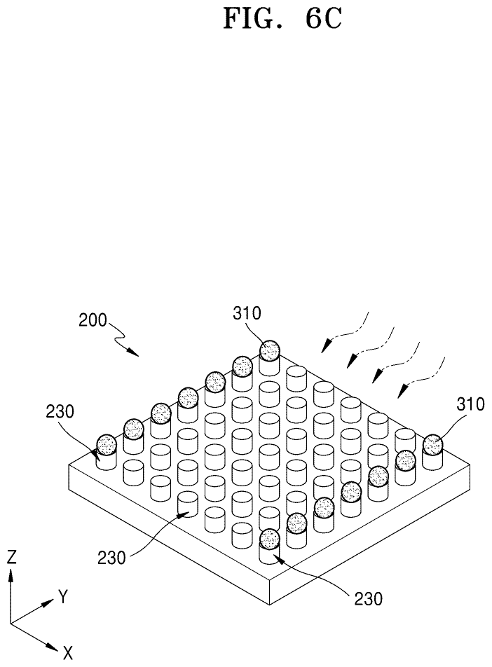

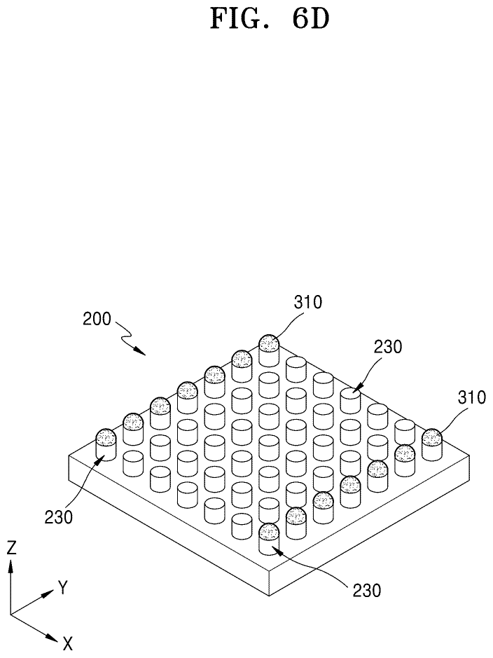

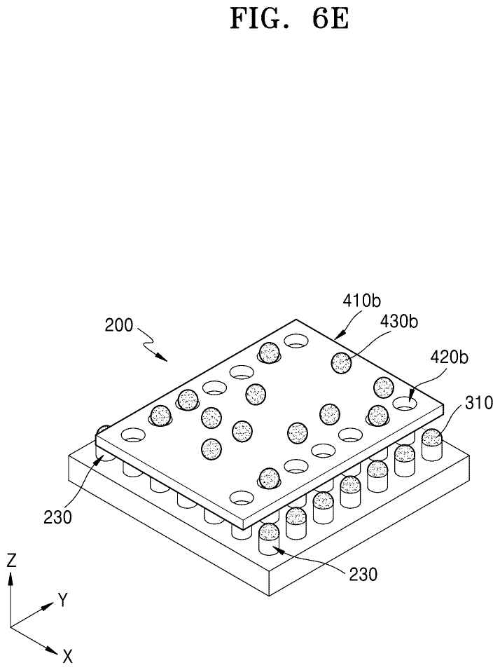

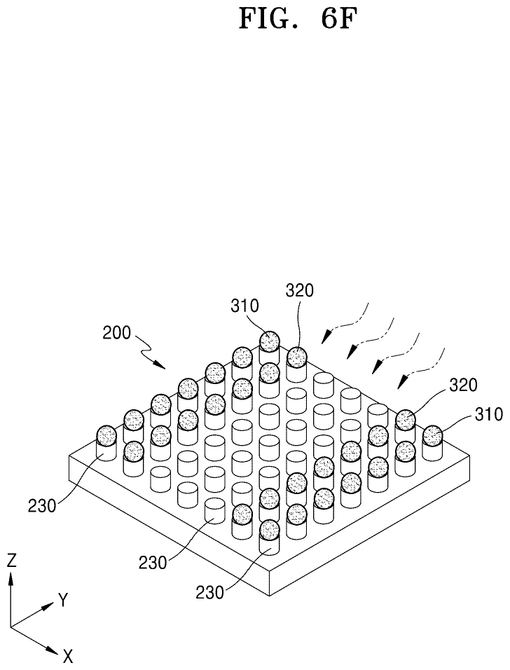

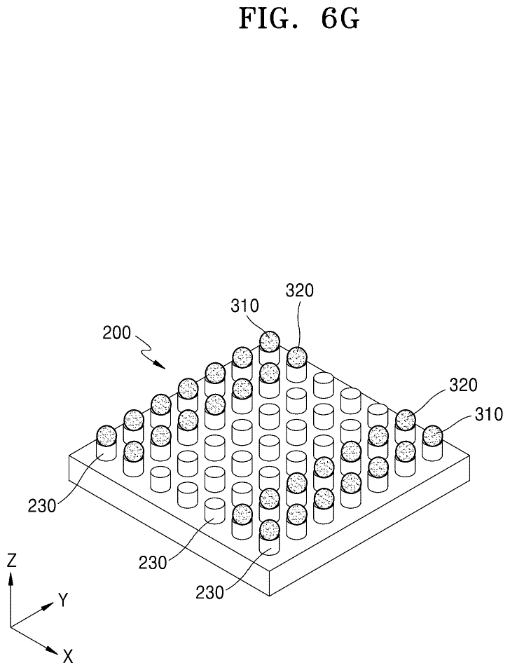

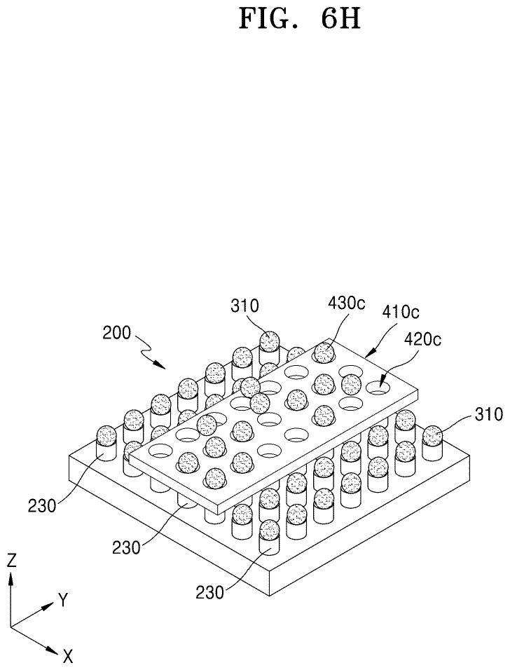

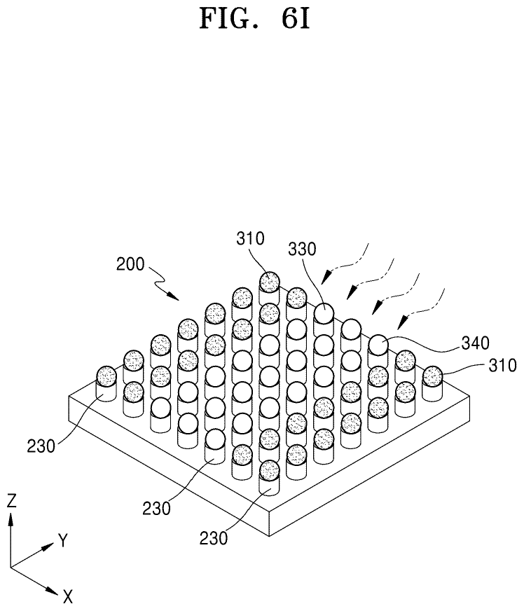

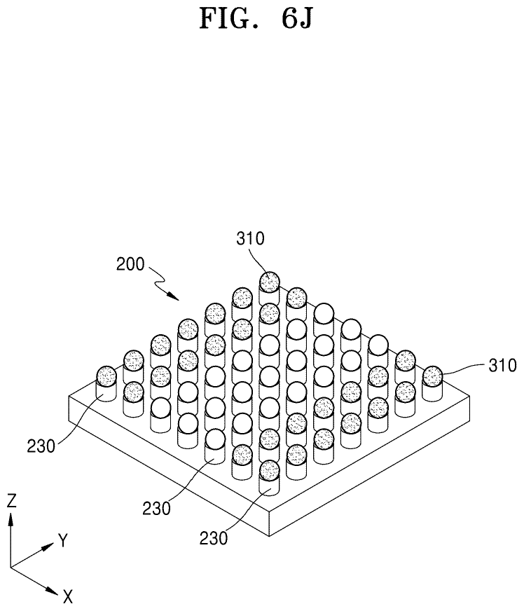

Specifically, in FIGS. 5 and 6A to 6J, the same member numbers as shown in FIGS. 1 to 3 indicate the same members. Description of FIGS. 5 and 6A to 6J may be briefly provided or omitted when redundant with respect to descriptions provided with reference to FIGS. 1 and 3. The planar layout diagram SBL of FIG. 5 and the perspective views of FIGS. 6A to 6J illustrate connection balls 300 arranged on the bottom surface 210b of the substrate body 210 constituting the package substrate 200. FIG. 1 may be a cross-sectional view taken along line A-A′ of FIG. 5.

The package substrate 200, that is, the substrate body 210, may be formed in a rectangular shape. The connection balls 300 may be arranged on the substrate pads 230 arranged on the bottom surface 210b of the substrate body 210. The substrate protection layer 220 that insulates the substrate pads 230 may be arranged on the bottom surface 210b of the substrate body 210.

The connection balls 300 may include the first metal core solder balls 310, the second metal core solder balls 320, the first core-free solder balls 330, and the second core-free solder balls 340.

The first metal core solder balls 310 and the second metal core solder balls 320 may be arranged in the package substrate 200, that is, on the outer peripheral portions (e.g., the first outer peripheral portions CSBR1-1 and the second outer peripheral portions CSBR1-2) of the substrate body 210. The first metal core solder balls 310 may be arranged on the first outer peripheral portions CSBR1-1 near the two-sided edges of the package substrate 200, which may be rectangular. The first outer peripheral portions CSBR1-1 may be outer peripheral portions closest to the respective two-sided edges of the package substrate 200. The second metal core solder balls 320 may be arranged at the second outer peripheral portions CSBR1-2 adjacent to the first outer peripheral portions CSBR1-1 of the package substrate 200. The second outer peripheral portions CSBR1-2 may be located on the outer peripheral portions of the substrate body 210, but may be located relatively close to the central portion of the substrate body 210 compared to the first outer peripheral portions CSBR1-1.

In some embodiments, the first metal core solder balls 310 may be arranged only at the first outer peripheral portions CSBR1-1, and the second metal core solder balls 320 may be arranged only at the second outer peripheral portions CSBR1-2. In some embodiments, the first metal core solder balls 310 and the second metal core solder balls 320 of FIG. 5 are all arranged near the two-sided edges of the package substrate 200, but may not be arranged near some edges.

The first core-free solder balls 330 and the second core-free solder balls 340 may be arranged in the package substrate 200, that is, on the central portion SBR of the substrate body 210. The first core-free solder balls 330 and the second core-free solder balls 340 may be arranged on the second outer peripheral portions CSBR1-2 of the package substrate 200. The second core-free solder balls 340 may be arranged at a center of the central portion SBR of the substrate body 210. A plurality of second core-free solder balls 340 may be provided, and the plurality of second core-free solder balls 340 may be arranged side by side in the second horizontal direction (Y direction). A plurality of first core-free solder balls 330 may also be provided, and the plurality of first core-free solder balls 330 may also be arranged side by side in rows in the second horizontal direction (Y direction). In this case, the plurality of first core-free solder balls 330 forming one row and the plurality of first core-free solder balls 330 forming another row, with the second core-free solder ball 340 therebetween, may be arranged to be spaced apart in the second horizontal direction (Y direction).

FIGS. 6A to 6J are perspective views illustrating a process of forming solder balls (e.g., connection balls 300) on substrate pads 230 of the package substrate of FIGS. 1 and 5.

Referring to FIG. 6A, the plurality of substrate pads 230 are formed on the package substrate 200. The plurality of substrate pads 230 are arranged to be spaced apart from each other in the first horizontal direction (X direction) and the second horizontal direction (Y direction).

The diameters of the plurality of substrate pads 230 formed on the package substrate 200 may be the same. However, depending on embodiments, the diameter of the substrate pad arranged at the outermost peripheral portion of the package substrate 200 is the largest, and the diameters of the substrate pads may decrease toward the central portion of the package substrate 200.

Referring to FIG. 6B, a first solder mask 410a having first openings 420a is arranged on the package substrate 200. The first openings 420a arranged in the first solder mask 410a may be formed to correspond to the substrate pads 230. A first metal core solder material 430a is coated or applied on the first solder mask 410a.

Referring to FIG. 6C, the first metal core solder material 430a may pass through the first openings 420a formed in the first solder mask 410a of FIG. 6B to form a first metal core solder ball 310 on a plurality of the substrate pads 230. The substrate pads 230 and the first metal core solder balls 310 are coupled to each other through heat treatment.

Referring to FIG. 6D, the first metal core solder balls 310 may be formed on some of the substrate pads 230 of the package substrate 200. The first metal core solder balls 310 may be formed in outer peripheral portions of the package substrate 200.

Referring to FIG. 6E, a second solder mask 410b having second openings 420b is arranged on the package substrate 200. The second openings 420b arranged in the second solder mask second solder mask 410b may be openings arranged closer to the central portion of the package substrate 200 than the first openings 420a of the first solder mask 410a of FIG. 6B.

Referring to FIG. 6F, the second metal core solder material 430b may pass through the second openings 420b formed in the second solder mask 410b of FIG. 6E to form a second metal core solder ball 320 on a plurality of the substrate pads 230. The substrate pads 230 and the second metal core solder balls 320 are coupled to each other through heat treatment.

Referring to FIG. 6G, the second metal core solder balls 320 may be formed on some of the substrate pads 230 of the package substrate 200. The second metal core solder balls 320 may be formed closer to the central portion of the package substrate 200 than the first metal core solder balls 310.

FIGS. 6H to 6J are perspective views illustrating a process of forming the first core-free solder balls 330 and the second core-free solder balls 340 on the substrate pads 230 of the package substrate 200.

Referring to FIG. 6H, a third solder mask 410c having third openings 420c is arranged on the package substrate 200 following the process of FIG. 6G being performed. The third openings 420c arranged in the third solder mask 410c may be formed to correspond to the substrate pads 230. A core-free solder material 430c is coated or applied on the third solder mask 410c. In this case, the third openings 420c of the third solder mask 410c may be openings arranged in rows and columns in the package substrate 200. The first openings 420a illustrated in FIG. 6B, the second openings 420b illustrated in FIG. 6E, and the third openings 420c illustrated in FIG. 6H may all have the same size. In addition, the first metal core solder material 430a shown in FIG. 6B, the second metal core solder material 430b shown in FIG. 6E, and the core-free solder material 430c shown in FIG. 6H may all have a spherical shape with the same volume.

Referring to FIG. 61, the core-free solder material 430c passes through the third openings 420c formed in the third solder mask 410c of FIG. 6H to form the first core-free solder balls 330 on the substrate pads 230. Subsequently, the substrate pads 230 and the first core-free solder balls 330 are coupled to each other through heat treatment.

Referring to FIG. 6J, the first core-free solder balls 330 may be formed on the substrate pads 230 of the package substrate 200. The first core-free solder balls 330 may be formed in a central portion of the package substrate 200.

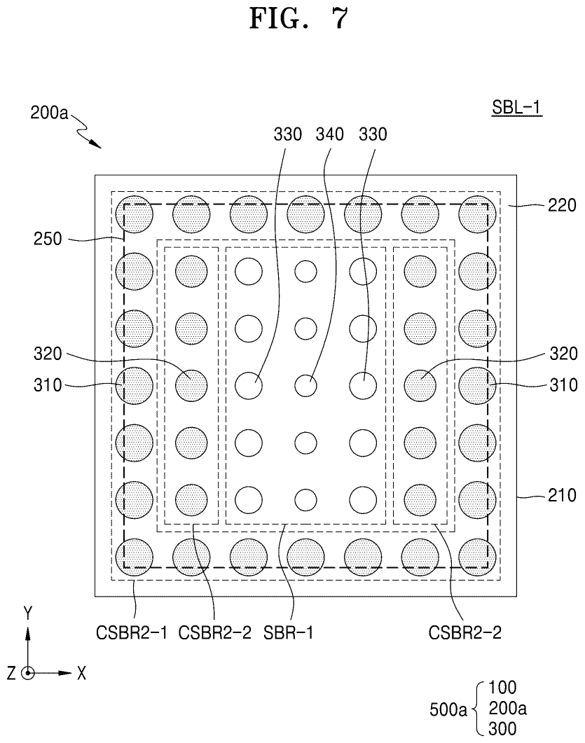

FIG. 7 is a planar layout diagram illustrating connection balls 300 arranged on substrate pads 230 of a package substrate 200a according to an embodiment.

Referring to FIG. 7, a planar layout SBL-1 of FIG. 7 may be another example of the planar layout SBL of FIG. 5. The planar layout SBL-1 of FIG. 7 may be the same as the planar layout SBL of FIG. 5, except that the first metal core solder balls 310 are arranged near the four edges of a package substrate 200a, which may be rectangular. Reference numbers of FIG. 7, which are identical to or similar to those of FIGS. 1 and 5, indicate the same or similar members. Description of FIG. 7 may be briefly provided or omitted when redundant with respect to descriptions provided with reference to FIGS. 1 and 5.

The planar layout diagrams SBL-1 of FIG. 7 illustrates connection balls 300 arranged on the bottom surface 210b (see FIG. 1) of the substrate body 210 constituting the package substrate 200a. The package substrate 200a, that is, the substrate body 210 may be formed in a rectangular shape. The connection balls 300 may be arranged on the substrate pads 230 arranged on the bottom surface 210b of the substrate body 210. The substrate protection layer 220 that insulates the substrate pads 230 may be arranged on the bottom surface 210b of the substrate body 210.

The connection balls 300 may include the first metal core solder balls 310, the second metal core solder balls 320, the first core-free solder balls 330, and the second core-free solder balls 340.

The first metal core solder balls 310 may be arranged on the package substrate 200a, that is, the first outer peripheral portion CSBR2-1 of the substrate body 210. The first outer peripheral portion CSBR2-1 may be a quadrangular ring-shaped region extending along the vicinity of the edges of the four surfaces of the package substrate 200a.

Second metal core solder balls 320 may be arranged on the package substrate 200a, that is, the second outer peripheral portions CSBR2-2 of the substrate body 210. The second outer peripheral portions CSBR2-2 may be regions surrounded by the first outer peripheral portion CSBR2-1 having a quadrangular ring shape in the package substrate 200a. The second outer peripheral portions CSBR2-2 may be regions extending in the second horizontal direction (Y direction) along the vicinity of the two-sided edges. The second outer peripheral portions CSBR2-2 may be regions having a rectangular shape and surrounded by the first outer peripheral portion CSBR2-1.

In some embodiments, the first metal core solder balls 310 and the second metal core solder balls 320 may be arranged in at least one from among the first outer peripheral portion CSBR2-1 and the second outer peripheral portions CSBR2-2. In some embodiments, all of the first metal core solder balls 310 of FIG. 7 are arranged near the four-sided edges of the package substrate 200a, but may not be arranged near some of the four-sided edges of the package substrate 200a according to embodiments.

The first core-free solder balls 330 and the second core-free solder balls 340 may be arranged in the package substrate 200a, that is, the central portion SBR-1 of the substrate body 210. The first core-free solder balls 330 and the second core-free solder balls 340 may be arranged inside the first outer peripheral portion CSBR2-1 and the second outer peripheral portion CSBR2-2 of the package substrate 200a.

The diameters of the substrate pads 230 on which the first core-free solder balls 330, the second core-free solder balls 340, the first metal core solder balls 310, and the second metal core solder balls 320 are arranged may be the same.

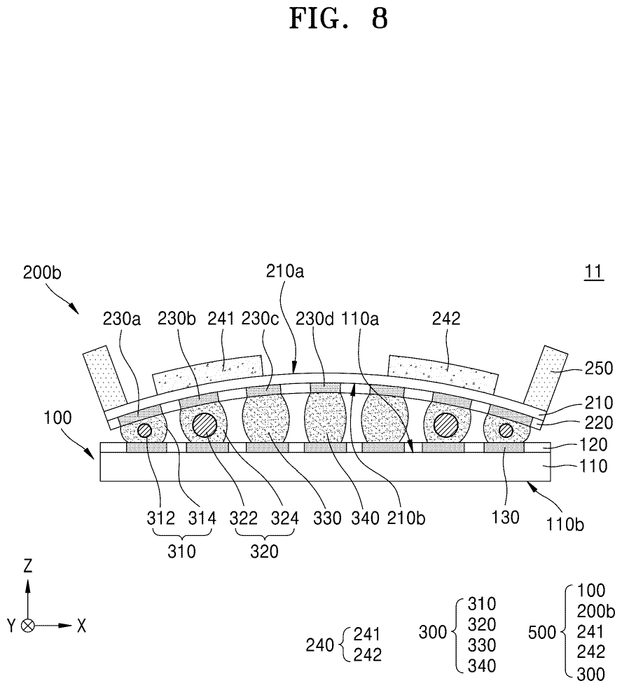

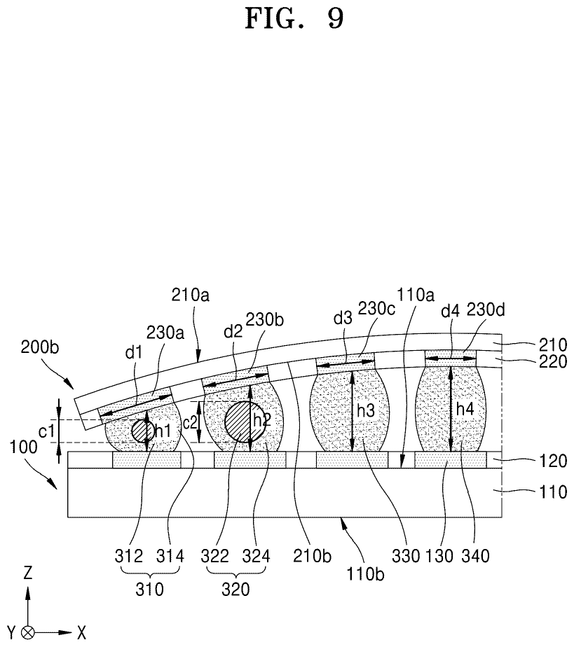

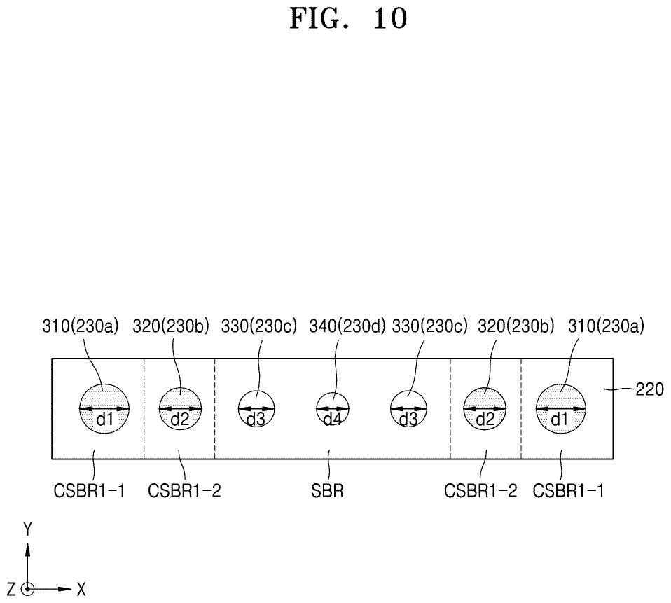

FIG. 8 is a cross-sectional view illustrating a semiconductor package 11 according to an embodiment, and FIG. 9 is a partially enlarged cross-sectional view of the semiconductor package 11 shown in FIG. 8. FIG. 10 is a partially enlarged planar layout diagram of the semiconductor package shown in FIG. 8.

A semiconductor package 11 shown in FIG. 8 is substantially identical or similar to the semiconductor package 10 shown in FIGS. 1 to 3, except that diameters of the plurality of substrate pads (e.g., the first substrate pad 230a, the second substrate pad 230b, the third substrate pad 230c, and the fourth substrate pad 230d) arranged on the bottom surface of the substrate body 210 differ depending on the locations thereof. Hereinafter, the semiconductor package 11 illustrated in FIG. 8 will be mainly described in terms of differences from the semiconductor package 10 illustrated in FIGS. 1 to 3, and repeated description of the components already mentioned may be omitted or simplified.

A modular semiconductor package 500b may include a board substrate 100, a package substrate 200b, and a plurality of connection balls 300. The package substrate 200b of the semiconductor package 11 may include a plurality of substrate pads (e.g., first substrate pads 230a, second substrate pads 230b, third substrate pad 230c, and fourth substrate pads 230d) arranged on a bottom surface of a substrate body 210. In this case, the plurality of substrate pads) may include first substrate pads 230a, second substrate pads 230b, third substrate pads 230c, and fourth substrate pads 230d. A plurality of metal core solder balls (e.g., first metal core solder balls 310 and second metal core solder balls 320) may be attached to the first substrate pads 230a and the second substrate pads 230b, respectively, and a plurality of core-free solder balls (e.g., the first core-free solder balls 330 and the second core-free solder balls 340) may be attached to the third substrate pads 230c and the fourth substrate pads 230d, respectively.

As described above, the package substrate 200b may have a warpage in a manufacturing process. For example, as described above, the package substrate 200b, that is, the substrate body 210, may have a positive warpage convex upward. Accordingly, the plurality of metal core solder balls (e.g., the first metal core solder balls 310 and the second metal core solder balls 320) may be arranged at outer peripheral portions of the package substrate 200b.

Diameters of the plurality of substrate pads (e.g., the first substrate pads 230a, the second substrate pads 230b, the third substrate pads 230c, and the fourth substrate pads 230d) may be configured to decrease from the outer peripheral portion to the central portion of the package substrate 200b. A first metal core solder ball 310 may be arranged on the first substrate pad 230a arranged at the outermost peripheral portion of the package substrate 200b, and a second core-free solder ball 340 may be arranged on the fourth substrate pad 230d arranged at the central portion of the package substrate 200b. In addition, a second metal core solder ball 320 may be arranged on the second substrate pad 230b arranged between the first substrate pad 230a and the third substrate pad 230c in the first horizontal direction (X direction), and a first core-free solder ball 330 may be arranged on the third substrate pad 230c arranged between the second substrate pad 230b and the fourth substrate pad 230d in the first horizontal direction (X direction).

The first metal core solder ball 310, the second metal core solder ball 320, the first core-free solder ball 330, and the second core-free solder ball 340 may have the same volume as each other. However, since the package substrate 200b has a positive warpage that is convex upward, heights, in the vertical direction (Z direction), of the plurality of connection balls 300 connected to the board substrate 100, which is flat, decrease from the central portion to the outer peripheral portion of the package substrate 200b. Although the plurality of connection balls 300 have the same volume, the heights in the vertical direction (Z direction) may be different from each other, and thus the widths in the lateral direction (X direction and/or Y direction) may also be changed in inverse proportion to the heights in the vertical direction (Z direction). The diameters of the plurality of substrate pads (e.g., the first substrate pads 230a, the second substrate pads 230b, the third substrate pads 230c, and the fourth substrate pads 230d) may vary depending upon the varying widths of the connection balls 300 in the lateral direction (X direction and/or Y direction).

The first substrate pads 230a may be located at the first outer portions CSBR1-1 of the substrate body 210, and the second substrate pads 230b may be located at the second outer peripheral portions CSBR1-2 of the substrate body 210. In addition, the third substrate pads 230c and the fourth substrate pads 230d may be located at the central portion SBR of the substrate body 210.

The first metal core solder balls 310 may be arranged on the package substrate 200b, that is, on the first outer peripheral portion CSBR1-1 of the substrate body 210. The first metal core solder balls 310 may be arranged on the first outer peripheral portions CSBR1-1 near the two-sided edges of the package substrate 200b, which may be rectangular.

In some embodiments, the first metal core solder balls 310 may be arranged only on the first outer peripheral portions CSBR1-1. In some embodiments, the first metal core solder balls 310 of FIG. 10 are all arranged near the two-sided edges of the package substrate 200b, but may not be arranged near some edges.

The first core-free solder balls 330 and the second core-free solder balls 340 may be arranged in the package substrate 200b, that is, on the central portion SBR of the substrate body 210. The first core-free solder balls 330 and the second core-free solder balls 340 may be arranged on the first outer peripheral portions CSBR1-1 of the package substrate 200b.

In some embodiments, the second metal core solder balls 320 may be arranged on the package substrate 200b, that is, on the second outer peripheral portions CSBR1-2 of the substrate body 210. The second metal core solder balls 320 may be arranged at the second outer peripheral portion CSBR1-2 positioned between the first outer peripheral portion CSBR1-1 and the central portion SBR of the package substrate 200b.

Diameters of the plurality of substrate pads (e.g., the first substrate pads 230a, the second substrate pads 230b, the third substrate pads 230c, and the fourth substrate pads 230d) in which the plurality of connection balls 300 are arranged may be different from each other in the outer peripheral portions (e.g., the first outer peripheral portions CSBR1-1 and the second outer peripheral portions CSBR1-2) and the central portion SBR of the package substrate 200b. For example, the diameters of the first substrate pads 230a on which the first metal core solder balls 310 are arranged may be greater than the diameters of the second substrate pads 230b on which the second metal core solder balls 320 are arranged. In addition, the diameters of the substrate pads may decrease toward the center of the package substrate 200b in the central portion SBR of the package substrate 200b. For example, the diameter of the third substrate pad 230c on which the first core-free solder ball 330 is arranged may be greater than the diameter of the fourth substrate pad 230d on which the second core-free solder ball 340 is arranged.

A diameter d1 of the first substrate pad 230a may be greater than a diameter d2 of the second substrate pad 230b, and the diameter d2 of the second substrate pad 230b may be greater than a diameter d3 of the third substrate pad 230c. In addition, the diameter d3 of the third substrate pad 230c may be greater than a diameter d4 of the fourth substrate pad 230d. Likewise, referring again to FIG. 9, the width of the first metal core solder ball 310 attached to the first substrate pad 230a may be greater than the width of the second metal core solder ball 320 attached to the second substrate pad 230b, and the width of the second metal core solder ball 320 may be greater than the width of the first core-free solder ball 330 attached to the third substrate pad 230c. In addition, the width of the first core-free solder ball 330 may be greater than the width of the second core-free solder ball 340 attached to the fourth substrate pad 230d.

As described above, the first metal core solder balls 310, the second metal core solder balls 320, the first core-free solder balls 330, and the second core-free solder balls 340 have the same volume. However, since the heights of the first metal core solder balls 310, the second metal core solder balls 320, the first core-free solder balls 330, and the second core-free solder balls 340 may be different from each other depending on the warpage of the package substrate 200b, the widths of the first metal core solder balls 310, the second metal core solder balls 320, the first core-free solder balls 330, and the second core-free solder balls 340 in the lateral direction (X direction and/or Y direction) may also be changed correspondingly.

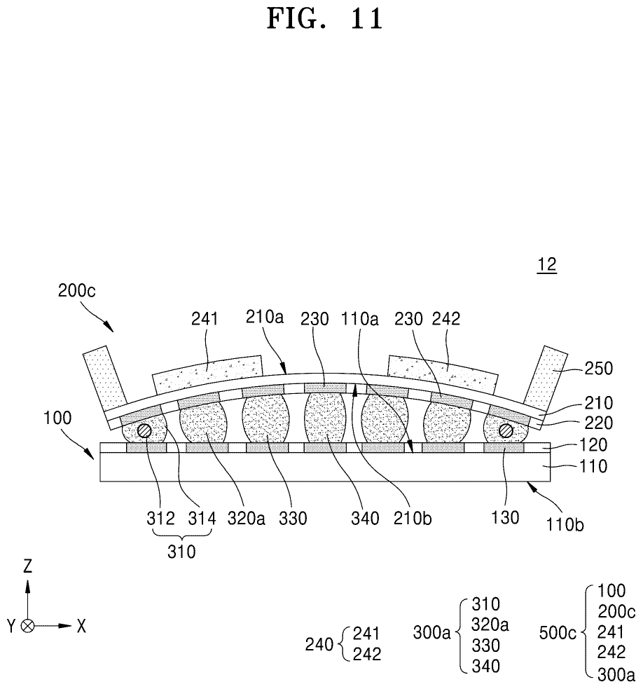

FIG. 11 is a cross-sectional view illustrating a semiconductor package 12 according to an embodiment.

A semiconductor package 12 illustrated in FIG. 11 is almost the same as or similar to the semiconductor package 10 illustrated in FIG. 1, except that a plurality of connection balls 300a do not include second metal core solder balls. Accordingly, repeated description of the components already given with respect to FIG. 1 may be omitted or briefly given.

Referring to FIG. 11, a semiconductor package 12 may include a board substrate 100, a package substrate 200c, and connection balls 300a. In this case, the connection balls 300a may include a first metal core solder ball 310 arranged near the outermost peripheral edge of the package substrate 200c, and first core-free solder balls 330 and second core-free solder balls 340 arranged in the central portion of the package substrate 200c. In this case, the first metal core solder balls 310, the first core-free solder balls 330, and the second core-free solder balls 340 are the same as the first metal core solder balls 310, the first core-free solder balls 330, and the second core-free solder balls 340 described with reference to FIG. 1, and thus, repeated description thereof may be omitted.

The connection balls 300a may include third core-free solder balls 320a positioned between the first metal core solder balls 310 and the first core-free solder balls 330 in the first horizontal direction (X direction). The third core-free solder ball 320a may be a connection ball that does not include a metal core and includes only a solder material. The third core-free solder ball 320a may have substantially the same size as the second metal core solder ball 320 illustrated in FIG. 1.

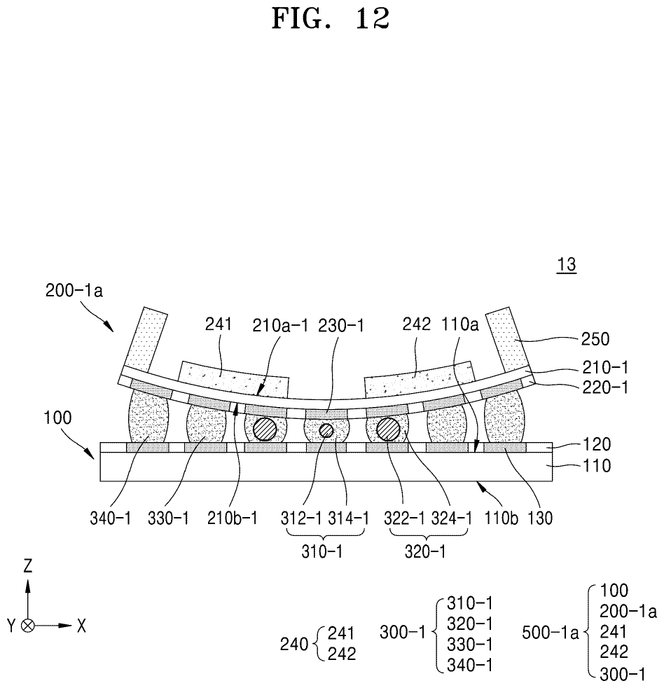

FIG. 12 is a cross-sectional view illustrating a semiconductor package 13 including a package substrate 200-1a having a negative warpage according to an embodiment.

Specifically, the semiconductor package 13 may be the same as the semiconductor package 10 of FIG. 1, except that a package substrate 200-1a has a negative warpage that is convex downward. Reference numbers of FIG. 12, which are identical to or similar to those of FIG. 1, indicate the same or similar members. Repeated description of components in FIG. 12 that are identical to or similar to FIG. 1 may be briefly described or omitted.

The semiconductor package 13 may include a modular semiconductor package 500-1a including a board substrate 100, a package substrate 200-1a, connection balls 300-1, and a plurality of semiconductor devices (e.g., a first semiconductor device 241 and a second semiconductor device 242). The board substrate 100 may include a board body 110 having a top surface 110a and a bottom surface 110b, a plurality of board pads 130, and a board protection layer 120. The board substrate 100 may refer to the board body 110 in a narrow sense (a limited sense).

The package substrate 200-1a may include a substrate body 210-1 having a top surface 210a-1 and a bottom surface 210b-1, a plurality of substrate pads 230-1 arranged to be spaced apart from each other on the bottom surface 210b-1 of the substrate body 210-1, and a substrate protection layer 220-1 to insulate the substrate pads 230-1. The package substrate 200-1a may refer to the substrate body 210-1 in a narrow sense (a limited sense).

The package substrate 200-1a may have a warpage in a manufacturing process. In some embodiments, the package substrate 200-1a, that is, the substrate body 210-1, may have a negative warpage convex downward.

The plurality of semiconductor devices (e.g., the first semiconductor device 241 and the second semiconductor device 242) are spaced apart from each other on the package substrate 200-1a, that is, on the top surface 210a-1 of the substrate body 210-1. The plurality of semiconductor devices may include a first semiconductor device 241 and a second semiconductor device 242.

A structure including the package substrate 200-1a and the plurality of semiconductor devices (e.g., the first semiconductor device 241 and the second semiconductor device 242) arranged on the package substrate 200-1a may be referred to as the modular semiconductor package 500-1a. In this embodiment, the plurality of semiconductor devices (e.g., the first semiconductor device 241 and the second semiconductor device 242) are arranged on the package substrate 200-1a, but semiconductor chips may be arranged on the package substrate 200-1a.

Connection balls 300-1 may be arranged between the board substrate 100 and the package substrate 200-1a to electrically connect the board pads 130 and the substrate pads 230-1 to each other. The connection balls 300-1 may include first metal core solder balls 310-1, second metal core solder balls 320-1, first core-free solder balls 330-1, and second core-free solder balls 340-1. The first metal core solder ball 310-1 may include a first metal core 312-1 and a first core solder layer 314-1 surrounding the first metal core 312-1, and the second metal core solder ball 320-1 may include a second metal core 322-1 and a second core solder layer 324-1 surrounding the second metal core 322-1.

The first core-free solder balls 330-1 and the second core-free solder balls 340-1 may refer to solder balls without a metal core. The first core-free solder balls 330-1 and the second core-free solder balls 340-1 may include the same material as the first core solder layer 314-1 and the second core solder layer 324-1. The first metal core solder balls 310-1, the second metal core solder balls 320-1, the first core-free solder balls 330-1, and the second core-free solder balls 340-1 may be arranged on the substrate pads 230-1 to electrically connect the board pads 130 to the substrate pads 230-1.

A plurality of substrate pads 230-1 may have the same diameter. As described above, the package substrate 200-1a may have a warpage in a manufacturing process. For example, as described above, the package substrate 200-1a, that is, the substrate body 210-1, may have a downwardly convex negative warpage. Accordingly, the first metal core solder balls 310-1 and the second metal core solder balls 320-1 are arranged in the central portion of the package substrate 200-1a.

In particular, the first metal core solder ball 310-1 may be positioned in the center of the package substrate 200-1a, and the second metal core solder balls 320-1 may be positioned to be spaced apart from each other in the first horizontal direction (X direction) with the first metal core solder ball 310-1 therebetween. Since the substrate body 210-1 has a negative warpage, the height of the first metal core solder ball 310-1, located in the center portion, in the vertical direction (Z direction) may be less than the heights of the second metal core solder balls 320-1 in the vertical direction (Z direction).

In addition, the second core-free solder balls 340-1 may be located near the outermost peripheral edges of the package substrate 200-1a, and each of the first core-free solder balls 330-1 may be located between the second core-free solder balls 340-1 and the second metal core solder balls 320-1. Like the first metal core solder balls 310-1 and the second metal core solder balls 320-1, since the substrate body 210-1 has a negative warpage, the heights of the outermost second core-free solder balls 340-1 in the vertical direction (Z direction) may be greater than the heights of the first core-free solder balls 330-1 in the vertical direction (Z direction).

The package substrate 200-1a, that is, the substrate body 210-1, may have a negative warpage convex downward. Accordingly, the first metal core solder ball 310-1 and the second metal core solder balls 320-1 may be arranged in the central portion of the package substrate 200-1. In particular, the first metal core solder ball 310-1 may be arranged at the central portion of the package substrate 200-1, and the second metal core solder ball 320-1 may be arranged closer to the outer peripheral portion of the package substrate 200-1 than the first metal core solder ball 310-1. Since the metal core solder balls are arranged on the central portion of the package substrate 200-1 having a negative warpage, short-circuit occurrence of the connection balls may be prevented in the central portion of the package substrate 200-1. When the volume of the solder material of the connection balls arranged in the central portion of the package substrate 200-1 is too great, the probability of occurrence of a short circuit with other adjacent connection balls may be high. To prevent this, in order to reduce the volume of the solder material contained in the connection balls in the central portion, the connection balls (e.g., the first metal core solder ball 310-1 and the second metal core solder balls 320-1) arranged in the central portion may include a metal core.

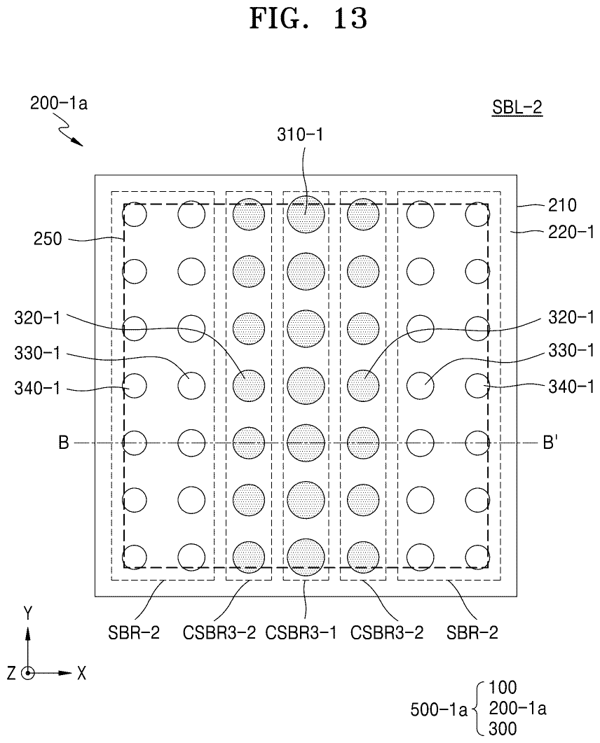

FIG. 13 is an example of a planar layout diagram showing connection balls 330-1 arranged on the substrate pads 230-1 of the package substrate 200-1a of FIG. 12.

Specifically, in FIG. 13, the same reference numerals as in FIG. 12 denote the same members. Description of FIG. 13 may be briefly provided or omitted when redundant with respect to descriptions provided with reference to FIG. 12. The planar layout diagram SBL-2 of FIG. 13 illustrates connection balls 300-1 arranged on the bottom surface 210b-1 (see FIG. 12) of the substrate body 210-1 constituting the package substrate 200-1a. FIG. 12 may be a cross-sectional view taken along line B-B′ of FIG. 13.

The package substrate 200-1a, that is, the substrate body 210-1 may be formed in a rectangular shape. The connection balls 300-1 may be arranged on the substrate pads 230-1 arranged on the bottom surface 210b-1 of the substrate body 210-1. The substrate protection layer 220 that insulates the substrate pads 230-1 may be arranged on the bottom surface 210b-1 of the substrate body 210-1.

The connection balls 300-1 may include first metal core solder balls 310-1, second metal core solder balls 320-1, first core-free solder balls 330-1, and second core-free solder balls 340-1. The first metal core solder balls 310-1 may be arranged on the package substrate 200-1a, that is, on the first central portion CSBR3-1 of the substrate body 210-1. In addition, the second metal core solder balls 320-1 may be arranged on the second central portions CSBR3-2 of the substrate body 210-1. In this case, the second central portions CSBR3-2 may be regions arranged to be spaced apart from each other on the package substrate 200-1a in the first horizontal direction (X direction) with the first central portion CSBR3-1 therebetween. The first core-free solder balls 330-1 and the second core-free solder balls 340-1 may be arranged in the package substrate 200-1a, that is, on the outer peripheral portions SBR-2 of the substrate body 210-1. The first core-free solder balls 330-1 and the second core-free solder balls 340-1 may be arranged on the outer peripheral portions SBR-2 extending along the two-sided edges in a rectangular shape of the package substrate 200-1a.

In the outer peripheral portions SBR-2, the first core-free solder balls 330-1 and the second core-free solder balls 340-1 may be arranged to have diameters that decrease toward the outermost peripheral edges of the substrate body 210-1. That is, the second core-free solder balls 340-1 each having a diameter less than the first core-free solder balls 330-1 may be located near the outermost two-sided edges of the substrate body 210.

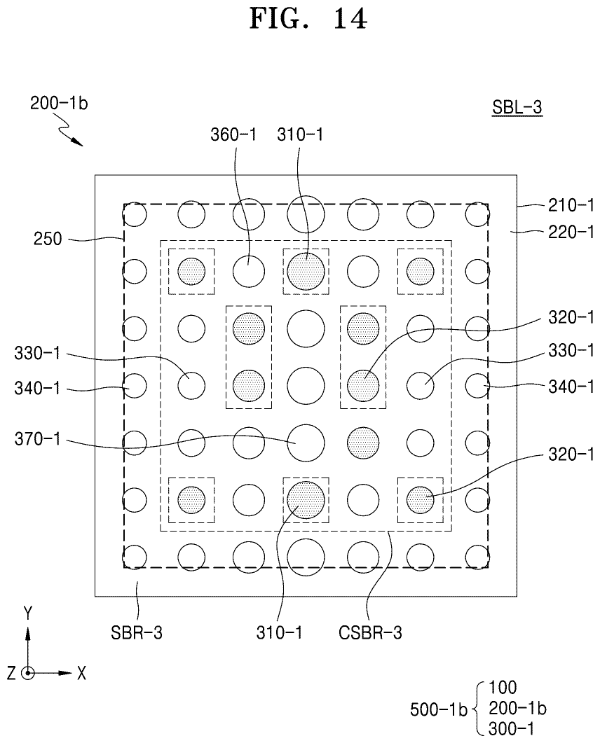

FIG. 14 is a planar layout diagram illustrating connection balls 300-1 arranged on substrate pads 230-1 of a package substrate 200-1b according to an embodiment.

In detail, the planar layout SBL-3 of FIG. 14 may be the same as the planar layout SBL-2 of FIG. 13, except that the first metal core solder balls 310-1 and the second metal core solder balls 320-1 are freely arranged on the bottom surface 210b-1 of the package substrate 200-1b. Reference numbers of FIG. 14, which are identical to or similar to those of FIGS. 12 and 13, indicate the same or similar members. Description of FIG. 14 may be briefly provided or omitted when redundant with respect to descriptions provided with reference to FIGS. 12 and 13.

The package substrate 200-1b, that is, the substrate body 210-1 may be formed in a rectangular shape. The connection balls 300-1 may be arranged on the substrate pads 230-1 arranged on the bottom surface 210b-1 of the substrate body 210-1. The substrate protection layer 220-1 that insulates the substrate pads 230-1 may be arranged on the bottom surface 210b-1 of the substrate body 210-1.

The connection balls 300-1 may include first metal core solder balls 310-1, second metal core solder balls 320-1, and core-free solder balls (e.g., first core-free solder balls 330-1, second core-free solder balls 340-1, third core-free solder balls 360-1, and fourth core-free solder balls 370-1). The first metal core solder balls 310-1 and the second metal core solder balls 320-1 may be freely arranged on the package substrate 200-1b, that is, the substrate body 210-1 regardless of a central portion or outer peripheral portions thereof. A plurality of core-free solder balls (e.g., the first core-free solder balls 330-1, the second core-free solder balls 340-1, the third core-free solder balls 360-1, and the fourth core-free solder balls 370-1) may be freely arranged on the package substrate 200-1b, that is, the substrate body 210-1 regardless of a central portion or outer peripheral portions thereof.

The first metal core solder balls 310-1 and the second metal core solder balls 320-1 may be arranged on a central portion CSBR-3 of the substrate body 210-1. In some embodiments, unlike FIG. 14, the first metal core solder balls 310-1 and the second metal core solder balls 320-1 may be arranged on the outer peripheral portion SBR-3 of the substrate body 210-1.

The plurality of core-free solder balls may include first core-free solder balls 330-1, second core-free solder balls 340-1, third core-free solder balls 360-1, and fourth core-free solder balls 370-1. Here, the third core-free solder ball 360-1 may be a connection ball having a smaller height in the vertical direction (Z direction) than heights of the first core-free solder ball 330-1 and the second core-free solder ball 340-1 and having a greater width in the lateral direction (X direction and/or Y direction) than widths of the first core-free solder ball 330-1 and the second core-free solder ball 340-1. In addition, the fourth core-free solder ball 370-1 may be a connection ball having a smaller height in the vertical direction (Z direction) than a height of the third core-free solder ball 360-1 and a greater width in the lateral direction (X direction and/or Y direction) than a width of the third core-free solder ball 360-1. The heights of the first core-free solder ball 330-1, the second core-free solder ball 340-1, the third core-free solder ball 360-1, and the fourth core-free solder ball 370-1 may increase in the order of the first core-free solder ball 330-1, the second core-free solder ball 340-1, the third core-free solder ball 360-1, and the fourth core-free solder ball 370-1 as described above.

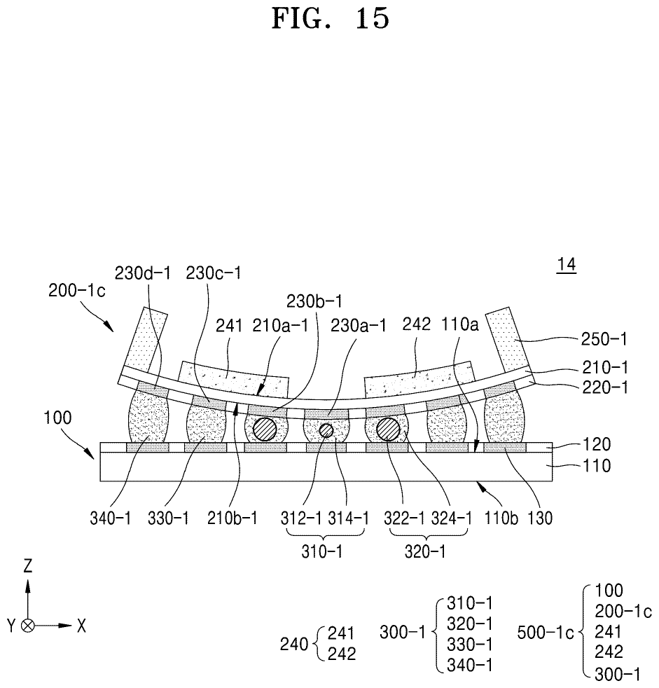

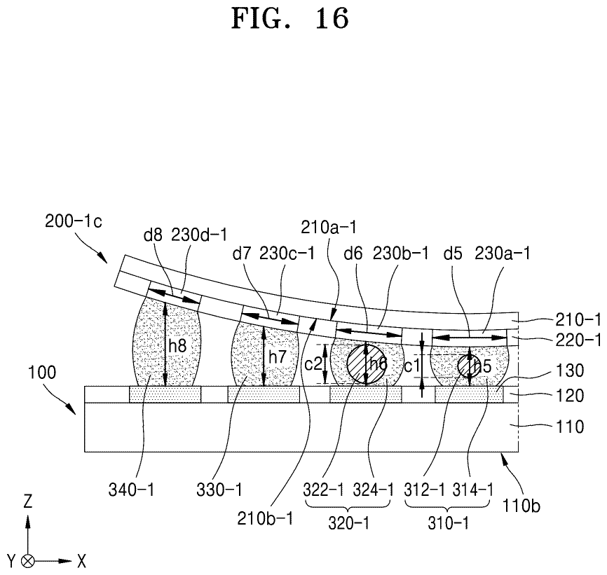

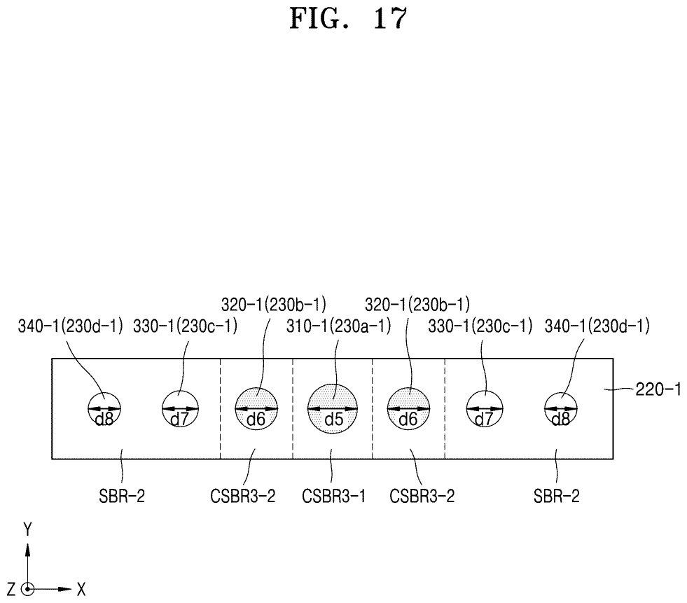

FIG. 15 is a cross-sectional view illustrating a semiconductor package 14 including a package substrate 200-1c having a negative warpage as a semiconductor package 14 according to an embodiment. FIG. 16 is a partially enlarged cross-sectional view of the semiconductor package 14 shown in FIG. 15. FIG. 17 is a partially enlarged planar layout diagram of the semiconductor package 14 shown in FIG. 15.

A semiconductor package 14 shown in FIG. 15 is substantially identical or similar to the semiconductor package 13 shown in FIG. 12, except that diameters of the plurality of substrate pads (e.g., the first substrate pad 230a-1, the second substrate pad 230b-1, the third substrate pad 230c-1, and the fourth substrate pad 230d-1) arranged on the bottom surface of the substrate body 210-1 differ depending on the locations thereof. Hereinafter, the semiconductor package 14 illustrated in FIG. 15 will be mainly described in terms of differences from the semiconductor package 13 illustrated in FIG. 12, and repeated description of the components already mentioned may be omitted or simplified.

A modular semiconductor package 500-1c may include a board substrate 100, a package substrate 200-1c, and a plurality of connection balls 300-1. The package substrate 200-1c of the semiconductor package 14 may include a plurality of substrate pads (e.g., first substrate pads 230a-1, second substrate pads 230b-1, third substrate pads 230c-1, and fourth substrate pads 230d-1) arranged on a bottom surface of a substrate body 210-1. In this case, the plurality of substrate pads may include first substrate pads 230a-1, second substrate pads 230b-1, third substrate pads 230c-1, and fourth substrate pads 230d-1. A plurality of metal core solder balls (e.g., first metal core solder balls 310-1 and second metal core solder balls 320-1) may be attached to the first substrate pads 230a-1 and the second substrate pads 230b-1, respectively, and a plurality of core-free solder balls (e.g., first core-free solder balls 330-1 and second core-free solder balls 340-1) may be attached to the third substrate pads 230c-1 and the fourth substrate pads 230d-1, respectively.

As described above, the package substrate 200-1c may have a warpage in a manufacturing process. For example, as described above, the package substrate 200-1c, that is, the substrate body 210-1, may have a downwardly convex negative warpage. Accordingly, the plurality of metal core solder balls (e.g., the first metal core solder balls 310-1 and the second metal core solder balls 320-1) may be arranged at a central portion of the package substrate 200-1c.

Diameters of the plurality of substrate pads (e.g., the first substrate pads 230a-1, the second substrate pads 230b-1, the third substrate pads 230c-1, and the fourth substrate pads 230d-1) may be configured to decrease from the central portion to the outer peripheral portion of the package substrate 200-1c. The first metal core solder ball 310-1 may be arranged on the first substrate pad 230a-1 arranged at the central portion of the package substrate 200-1c, and the second core-free solder balls (e.g., the first metal core solder balls 310-1 and the second metal core solder balls 320-1) may be arranged on the fourth substrate pads 230d-1 arranged at the outermost peripheral portion of the package substrate 200-1c. In addition, the second metal core solder ball 320-1 may be arranged on the second substrate pad 230b-1 arranged between the first substrate pad 230a-1 and the third substrate pad 230c-1 in the first horizontal direction (X direction), and the first core-free solder ball 330-1 may be arranged on the third substrate pad 230c-1 arranged between the second substrate pad 230b-1 and the fourth substrate pad 230d-1 in the first horizontal direction (X direction).

The first metal core solder balls 310-1, the second metal core solder balls 320-1, the first core-free solder balls 330-1, and the second core-free solder balls 340-1 may have the same volume as each other. However, since the package substrate 200-1c has a negative warpage that is convex downward, heights, in the vertical direction (Z direction), of the plurality of connection balls 300-1 connected to the board substrate 100, that is flat, decrease from the outer peripheral portion to the central portion of the package substrate 200-1c. Although the plurality of connection balls 300-1 have the same volume, the heights in the vertical direction (Z direction) may be different from each other, and thus the widths in the lateral direction (X direction and/or Y direction) may also be changed in inverse proportion to the heights in the vertical direction (Z direction). The diameters of the plurality of substrate pads (e.g., the first substrate pads 230a-1, the second substrate pads 230b-1, the third substrate pads 230c-1, and the fourth substrate pads 230d-1) may vary depending upon the varying widths of the connection balls 300-1 in the lateral direction (X direction and/or Y direction).

Since the package substrate 200-1c has a negative warpage, heights of the connection balls 300-1 decrease in the vertical direction (Z direction) from the outer peripheral portion of the package substrate 200-1c to the central portion thereof. That is, a height h5 of the first metal core solder ball 310-1 in the vertical direction (Z direction) is less than a height h6 of the second metal core solder ball 320-1 in the vertical direction (Z direction), and the height h6 of the second metal core solder ball 320-1 in the vertical direction (Z direction) is less than a height h7 of a first core-free solder ball 330-1 in the vertical direction (Z direction). In addition, the height h7 of the first core-free solder ball 330-1 in the vertical direction (Z direction) is less than a height h8 of a second core-free solder ball 340-1 in the vertical direction (Z direction).

The connection balls 300-1 may be arranged on the plurality of substrate pads (e.g., the first substrate pads 230a-1, the second substrate pads 230b-1, the third substrate pads 230c-1, and the fourth substrate pads 230d-1) arranged on the bottom surface of the substrate body 210-1.

The plurality of substrate pads may include first substrate pads 230a-1, second substrate pads 230b-1, third substrate pads 230c-1, and fourth substrate pads 230d-1. The first substrate pad 230a-1 may be located at the central portion of the substrate body 210-1 in a planar view, and a pair of second substrate pads 230b-1 may be arranged to be spaced apart from each other in the first horizontal direction (X direction) with the first substrate pad 230a-1 therebetween. In addition, a pair of fourth substrate pads 230d-1 may be located near the outermost peripheral edge of the substrate body 210-1 in a planar view, and a pair of third substrate pads 230c-1 may be located between the second substrate pad 230b-1 and the fourth substrate pad 230d-1 in the first horizontal direction (X direction).

The first metal core solder ball 310-1 may be arranged on the first substrate pad 230a-1, and the second metal core solder ball 320-1 may be arranged on the second substrate pad 230b-1. In addition, the first core-free solder ball 330-1 may be arranged on the third substrate pad 230c-1, and the second core-free solder ball 340-1 may be arranged on the fourth substrate pad 230d-1.

In this case, the first substrate pad 230a-1 may be located at the first central portion CSBR3-1 of the substrate body 210-1, and the second substrate pads 230b-1 may be located at the second central portions CSBR3-2 of the substrate body 210-1. In addition, the third substrate pads 230c-1 and the fourth substrate pads 230d-1 may be located at the outer peripheral portions SBR-2 of the substrate body 210-1.

The first core-free solder balls 330-1 and the second core-free solder balls 340-1 may be arranged in the package substrate 200-1c, that is, on the outer peripheral portions SBR-2 of the substrate body 210-1. The first core-free solder balls 330-1 and the second core-free solder balls 340-1 may be arranged on the outer peripheral portions SBR-2 near the two-sided edges of the package substrate 200-1c, which may be rectangular. In this case, the second core-free solder ball 340-1 having a width less than a width of the first core-free solder ball 330-1 in the lateral direction (X direction and/or Y direction) may be arranged at the outermost peripheral portion of the substrate body 210-1, and the second core-free solder ball 340-1 may be arranged closer to the central portion of the substrate body 210-1 than the first core-free solder ball 330-1.

The first metal core solder balls 310-1 may be arranged on the package substrate 200-1c, that is, on the first central portion CSBR3-1 of the substrate body 210-1. The second metal core solder balls 320-1 may be arranged on the second central portions CSBR3-2 positioned between the first central portion CSBR3-1 and the outer peripheral portion SBR-2 of the package substrate 200-1c.

Diameters of the plurality of substrate pads (e.g., the first substrate pads 230a-1, the second substrate pads 230b-1, the third substrate pads 230c-1, and the fourth substrate pads 230d-1) in which a plurality of connection balls 300-1 are arranged may be different from each other in the outer peripheral portions SBR-2, the first central portion CSBR3-1, and the second central portions CSBR3-2 of the package substrate 200-1c. For example, the diameter of the first substrate pad 230a-1 on which the first metal core solder ball 310-1 is arranged may be greater than the diameter of the second substrate pad 230b-1 on which the second metal core solder ball 320-1 is arranged. In addition, the diameter of the substrate pads may decrease toward the outermost peripheral portion of the package substrate 200-1c in the outer peripheral portion SBR-2 of the package substrate 200-1c. For example, the diameter of the fourth substrate pad 230d-1 on which the second core-free solder ball 340-1 is arranged may be less than the diameter of the third substrate pad 230c-1 on which the first core-free solder ball 330-1 is arranged.

A diameter d5 of the first substrate pad 230a-1 may be greater than a diameter d6 of the second substrate pad 230b-1, and the diameter d6 of the second substrate pad 230b-1 may be greater than a diameter d7 of the third substrate pad 230c-1. In addition, the diameter d7 of the third substrate pad 230c-1 may be greater than a diameter d8 of the fourth substrate pad 230d-1. Likewise, referring again to FIG. 16, the width of the first metal core solder ball 310-1 attached to the first substrate pad 230a-1 may be greater than the width of the second metal core solder ball 320-1 attached to the second substrate pad 230b-1, and the width of the second metal core solder ball 320-1 may be greater than the width of the first core-free solder ball 330-1 attached to the third substrate pad 230c-1. In addition, the width of the first core-free solder ball 330-1 may be greater than the width of the second core-free solder ball 340-1 attached to the fourth substrate pad 230d-1.

As described above, the first metal core solder balls 310-1 and the second metal core solder balls 320-1, the first core-free solder balls 330-1, and the second core-free solder balls 340-1 have the same volume as each other. However, since the heights of the first metal core solder balls 310-1, the second metal core solder balls 320-1, the first core-free solder balls 330-1, and the second core-free solder balls 340-1 may be different from each other depending on the warpage of the package substrate 200-1c, the widths of the first metal core solder balls 310-1, the second metal core solder balls 320-1, the first core-free solder balls 330-1, and the second core-free solder balls 340-1 in the lateral direction (X direction and/or Y direction) may also be changed correspondingly.

According to an embodiment, the diameter c1 of the first metal core 312-1 may be 0.3 to 0.9 times a height h5 of the adjacent core-free solder ball in the vertical direction (Z direction), and the diameter c2 of the second metal core 322-1 may be 0.5 to 0.9 times a height h6 of the closest core-free solder ball in the vertical direction (Z direction). For example, the diameter c1 of the first metal core 312-1 may be 0.3 to 0.9 times a height h7 of the first core-free solder ball 330-1 in the vertical direction (Z direction). In addition, the diameter c2 of the second metal core 322-1 may be 0.5 to 0.9 times the height h8 of the second core-free solder ball 340-1 in the vertical direction (Z direction). A description thereof is similar to that described with reference to FIG. 3, and thus a repeated description thereof may be omitted.

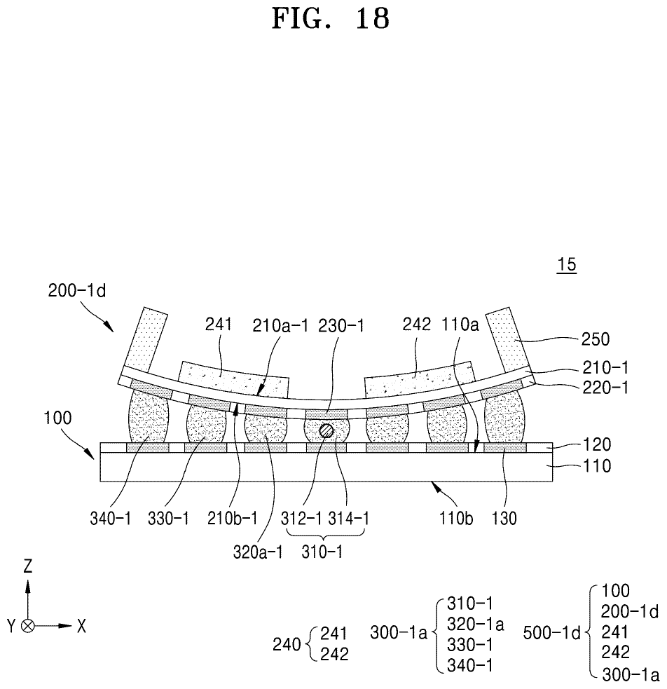

FIG. 18 is a cross-sectional view illustrating a semiconductor package 15 including a package substrate 200-1d having a negative warpage according to an embodiment.

The semiconductor package 15 illustrated in FIG. 18 is almost the same as or similar to the semiconductor package 14 illustrated in FIG. 12, except that a plurality of connection balls 300-1a include no second metal core solder balls. Accordingly, repeated description of the components already given with respect to FIG. 12 may be omitted or briefly given.

Referring to FIG. 18, a semiconductor package 15 may include a board substrate 100, a package substrate 200-1d, and connection balls 300-1a. In this case, the connection balls 300-1a may include first metal core solder balls 310-1 arranged in a central portion of the package substrate 200-1d, and first core-free solder balls 330-1 and second core-free solder balls 340-1 arranged outside the first metal core solder balls 310-1. In this case, the first metal core solder balls 310-1, the first core-free solder balls 330-1, and the second core-free solder balls 340-1 are the same as the first metal core solder balls 310-1, the first core-free solder balls 330-1, and the second core-free solder balls 340-1 described with reference to FIG. 12, and thus, repeated description thereof may be omitted.

The connection balls 300-1a may include third core-free solder balls 320a-1 positioned between the first metal core solder balls 310-1 and the first core-free solder balls 330-1 in the first horizontal direction (X direction). The third core-free solder ball 320a-1 may be a connection ball that does not include a metal core and includes only a solder material. The third core-free solder ball 320a-1 may have substantially the same size as the second metal core solder ball 320-1 illustrated in FIG. 12.

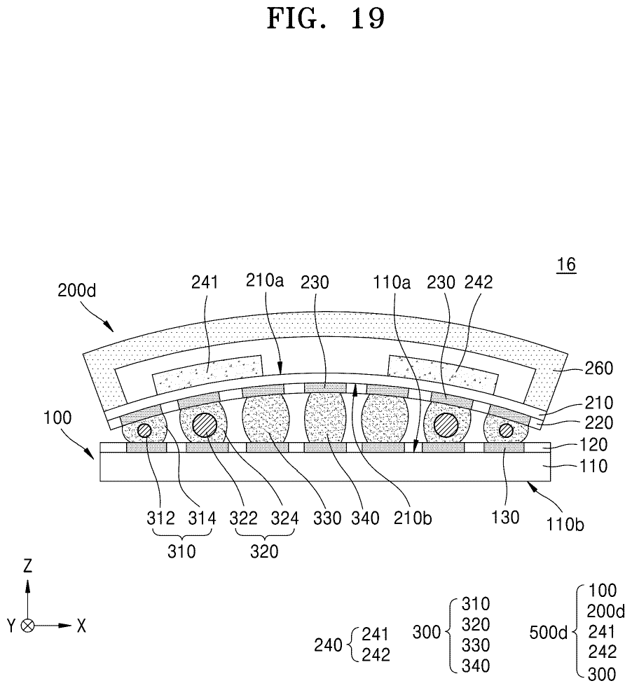

FIG. 19 is a cross-sectional view illustrating a semiconductor package 16 according to an embodiment.
the semiconductor package 16 shown in FIG. 19 is substantially the same as or similar to the semiconductor package 10 shown in FIG. 1, except that a heat slug 260 is included instead of a stiffener 250 (see FIG. 1) arranged on a top surface 210a of a substrate body 210. Accordingly, repeated description of the components already given with respect to FIG. 1 may be omitted or briefly given.

A package substrate 200d of a modular semiconductor package 500d may include a heat slug 260 arranged on the top surface 210a of the substrate body 210. The heat slug 260 may externally surround a first semiconductor device 241 and a second semiconductor device 242 mounted on the substrate body 210. The heat slug 260 may be formed on the substrate body 210 and may be configured to dissipate heat generated from the first semiconductor device 241 and the second semiconductor device 242. Since the heat slug 260 dissipates heat generated by the first semiconductor device 241 and the second semiconductor device 242, the semiconductor package 16 according to an embodiment may dissipate heat generated by the first semiconductor device 241 and the second semiconductor device 242, thereby improving the operational reliability of an entirety of the semiconductor package 16.

According to an embodiment, the heat slug 260 may include a metal, which is a material having a higher thermal conductivity than air. For example, the heat slug 260 may include copper (Cu), iron (Fe), nickel (Ni), cobalt (Co), tungsten (W), chromium (Cr) silver (Ag), gold (Au), platinum (Pt), tin (Sn), aluminum (Al), magnesium (Mg), silicon (Si), zinc (Zn), or a combination thereof.

The heat slug 260 may be attached to regions adjacent to outer peripheral edge portions on the top surface of the substrate body 210. In this case, since the substrate body 210 may have a warpage, the upper surface of the heat slug 260 may also be bent corresponding to the warpage of the substrate body 210.

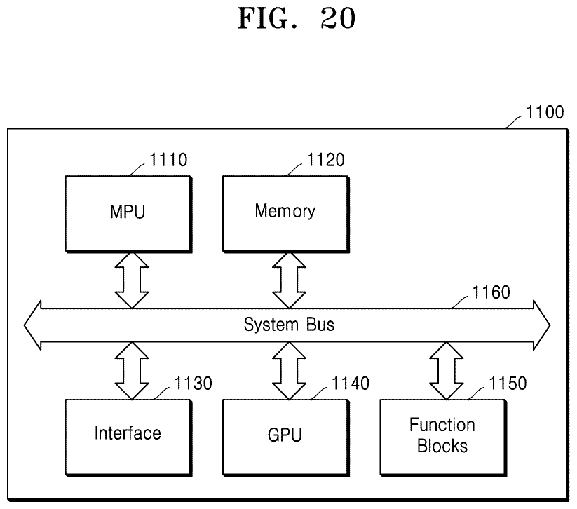

FIG. 20 is a block diagram schematically illustrating a configuration of a semiconductor package according to an embodiment.

Specifically, the semiconductor package 1100 may include a micro processing unit (MPU) 1110, a memory 1120, an interface 1130, a graphic processing unit (GPU) 1140, function blocks 1150, and a system bus 1160 connecting the MPU 1110, the memory 1120, the interface 1130, the GPU 1140, and the functional blocks 1150 with each other. The semiconductor package 1100 may include both the MPU 1110 and the GPU 1140, but may include only one of them.

The MPU 1110 may include a core and an L2 cache. For example, the MPU 1110 may include a multi-core. Each core of the multi-core may have the same or different performance. In addition, each core of the multi-core may be activated at the same time or may have a different time point at which it is activated. The memory 1120 may store results and the like processed by the function blocks 1150 under the control of the MPU 1110. For example, when data stored in an L2 cache of the MPU 1110 is flushed, the MPU 1110 may have the data be stored in the memory 1120. The interface 1130 may perform interfacing with external devices. For example, the interface 1130 may perform interfacing with a camera, a liquid crystal display (LCD), a speaker, and the like.

The GPU 1140 may perform graphic functions. For example, the GPU 1140 may perform a video codec or process a three-dimensional (3D) graphic. The function blocks 1150 may perform various functions. For example, when the semiconductor package 1100 is an application processor (AP) used in a mobile device, some of the function blocks 1150 may perform a communication function.

The semiconductor package 1100 may include any one of the semiconductor packages (e.g., the semiconductor packages 10, 11, 12, 13, 14, 15, 16) of embodiments of the present disclosure. The MPU 1110 and/or the GPU 1140 may include any one of the board level semiconductor packages (e.g., the semiconductor packages 10, 11, 12, 13, 14, 15, 16) described above. The memory 1120 may include any one of the board level semiconductor packages (e.g., the semiconductor packages 10, 11, 12, 13, 14, 15, 16) described above. The interface 1130 and the function blocks 1150 may include any one of the board level semiconductor packages (e.g., the semiconductor packages 10, 11, 12, 13, 14, 15, 16) described above.

While non-limiting example embodiments of the present disclosure have been described above with reference to the drawings, it will be understood that various changes in form and details may be made therein without departing from the spirit and scope of the present disclosure.

What is claimed is:

1. A semiconductor package comprising:
a package substrate comprising:
a substrate body comprising a top surface and a bottom surface opposite to the top surface; and
a plurality of substrate pads spaced apart from each other on the bottom surface; and
a plurality of connection balls connected to the plurality of substrate pads, wherein the plurality of connection balls comprise:
a metal core solder ball comprising a metal core; and
a plurality of core-free solder balls that each have a same volume as a volume of the metal core solder ball.

2. The semiconductor package of claim 1, wherein a diameter of a first substrate pad, among the plurality of substrate pads, that is connected to the metal core solder ball, is greater than diameters of second substrate pads, among the plurality of substrate pads, that are connected to the plurality of core-free solder balls.

3. The semiconductor package of claim 1, further comprising a board substrate comprising a plurality of board pads spaced apart from each other, wherein the plurality of connection balls are between the board substrate and the package substrate.

4. The semiconductor package of claim 3, wherein a height of each of the plurality of core-free solder balls in a vertical direction is greater than a height of the metal core solder ball in the vertical direction.

5. The semiconductor package of claim 1, further comprising:
at least one semiconductor device on the top surface of the substrate body; and
a stiffener extending along an outer edge of the substrate body, such as to be at a side of the at least one semiconductor device in a lateral direction.

6. The semiconductor package of claim 1, wherein the package substrate has positive warpage such that the package substrate is convex in an upward direction, or negative warpage such that the package substrate is convex in a downward direction.

7. The semiconductor package of claim 1, wherein the metal core solder ball is adjacent to an outer edge of the package substrate.

8. The semiconductor package of claim 1, wherein the plurality of core-free solder balls increase in height in a vertical direction toward a central portion of the package substrate.

9. The semiconductor package of claim 1, wherein the plurality of core-free solder balls increase in height in a vertical direction toward an outer edge of the package substrate.

10. The semiconductor package of claim 1, wherein a diameter of the metal core is 0.3 to 0.9 times a height, in a vertical direction, of a core-free solder ball closest to the metal core solder ball, among the plurality of core-free solder balls.

11. The semiconductor package of claim 1, wherein the metal core comprises at least one from among copper, nickel, and a polymer, and wherein the metal core has a melting point of 260° C. or more.

12. A semiconductor package comprising:
a package substrate comprising:
a substrate body comprising a top surface and a bottom surface opposite to the top surface; and
a plurality of substrate pads spaced apart from each other on the bottom surface; and
a plurality of connection balls connected to the plurality of substrate pads, wherein the plurality of connection balls comprise:
a first metal core solder ball comprising a first metal core;
a plurality of core-free solder balls; and
a second metal core solder ball between the first metal core solder ball and the plurality of core-free solder balls and comprising a second metal core having a diameter greater than a diameter of the first metal core,
wherein the first metal core solder ball, the second metal core solder ball, and the plurality of core-free solder balls have a same volume as each other.

13. The semiconductor package of claim 12, wherein a height of each of the plurality of core-free solder balls in a vertical direction is greater than a height of the second metal core solder ball in the vertical direction, and
wherein the height of the second metal core solder ball in the vertical direction is greater than a height of the first metal core solder ball in the vertical direction.

14. The semiconductor package of claim 12, wherein a diameter of a first substrate pad, among the plurality of substrate pads, connected to the first metal core solder ball is greater than a diameter of a second substrate pad, among the plurality of substrate pads, connected to the second metal core solder ball.

15. The semiconductor package of claim 12, wherein the package substrate comprises a rectangular shape from a horizontal perspective, and
wherein the first metal core solder ball is farther than the second metal core solder ball from a center of the package substrate.

16. The semiconductor package of claim 12, further comprising:
at least one semiconductor device on the top surface of the substrate body; and
a heat slug surrounding the at least one semiconductor device on the top surface of the substrate body.

17. The semiconductor package of claim 12, wherein a diameter of the first metal core is 0.3 to 0.9 times a height, in a vertical direction, of a core-free solder ball closest to the first metal core solder ball, among the plurality of core-free solder balls.

18. A semiconductor package comprising:
a package substrate comprising:
a substrate body comprising a top surface and a bottom surface opposite to the top surface, and
a plurality of substrate pads spaced apart from each other on the bottom surface; and
a plurality of connection balls connected to the plurality of substrate pads,
wherein the package substrate has negative warpage such that the package substrate is convex downward,
wherein the plurality of connection balls comprise:
a first metal core solder ball at a center of the package substrate and comprising a first metal core;
a second metal core solder ball adjacent to the first metal core solder ball and comprising a second metal core having a diameter greater than a diameter of the first metal core; and
a plurality of core-free solder balls adjacent to the second metal core solder ball, and
wherein the first metal core solder ball, the second metal core solder ball, and the plurality of core-free solder balls have a same volume as each other.

19. The semiconductor package of claim 18, further comprising a substrate protection layer on the bottom surface of the substrate body, the substrate protection layer configured to insulate the plurality of substrate pads.

20. The semiconductor package of claim 18, wherein the first metal core solder ball comprises a first core solder layer surrounding the first metal core,
wherein the second metal core solder ball comprises a second core solder layer surrounding the second metal core, and
wherein the first core solder layer, the second core solder layer, and the plurality of core-free solder balls comprise a same material as each other.
